(19) United States
(12) Patent Application Publication
(10) Pub. No.: US 2024/0105728 A1
(43) Pub. Date: Mar. 28, 2024

(54) TRANSISTOR DEVICES WITH DOUBLE-SIDE CONTACTS AND STANDARD CELL

(71) Applicant: QUALCOMM Incorporated, San Diego, CA (US)

(72) Inventors: Qingqing LIANG, San Diego, CA (US); Haining YANG, San Diego, CA (US); Jonghae KIM, San Diego, CA (US); Periannan CHIDAMBARAM, San Diego, CA (US); George Pete IMTHURN, San Diego, CA (US); Jun YUAN, San Diego, CA (US); Giridhar NALLAPATI, San Diego, CA (US); Deepak SHARMA, San Diego, CA (US)

(21) Appl. No.: 18/472,074

(22) Filed: Sep. 21, 2023

Related U.S. Application Data
(63) Continuation-in-part of application No. 17/934,400, filed on Sep. 22, 2022.

(51) Int. Cl. H01L 27/118

(52) U.S. Cl. CPC H01L 27/11807; H01L 2027/11853; H01L 2027/11866; H01L 2027/11875; H01L 2027/11881

(57) ABSTRACT

Disclosed are standard cells, transistors, and methods for fabricating the same. In an aspect, a transistor includes a drain and a source each including a first drain/source silicide layer on a frontside surface of the drain/source and a second drain/source silicide layer on a backside surface of the drain/source. The first drain silicide layer is coupled to a first drain contact structure or the second drain silicide layer is coupled to a second drain contact structure. The first source silicide layer is coupled to a first source contact structure or the second source silicide layer is coupled to a second source contact structure. A gate structure is disposed between the source and the drain. A channel is at least partially enclosed by the gate structure and disposed between the source and the drain and is recessed from the backside surfaces of the source and drain.

### CROSS-REFERENCE TO RELATED APPLICATIONS

The present application for patent is a Continuation-in-Part of U.S. patent application Ser. No. 17/934,400, entitled “TRANSISTOR DEVICES WITH DOUBLE-SIDE CONTACTS”, filed Sep. 22, 2022, assigned to the assignee hereof, and expressly incorporated herein by reference in its entirety.

### BACKGROUND OF THE DISCLOSURE

### 1. Field of the Disclosure

Aspects of the disclosure relate generally to three-dimensional integrated circuit (3DIC) devices including transistor devices with double-side or dual side contacts and further including double-side (e.g., frontside and/or backside) contacts in fin field-effect transistor (FinFET) and Gate-All-Around (GAA) devices and standard cells including device with frontside and backside contacts for the gate, source and/or drain.

### 2. Description of the Related Art

Integrated circuit technology has achieved great strides in advancing computing power through miniaturization components such as semiconductor transistors. The progression of semiconductors has progressed from bulk substrates and planar CMOS, FinFETs, nanowires or nanoribbons, FinFET 3D stacking to nanowire or nanoribbon 3D stacking. 3DIC is one of the main trends for very large-scale integration (VLSI) devices in the More Moore era. Through-silicon via is an important process module that allows 3D stacking. One industry trend is to vertically stack active chips (e.g., system on chip (SOC)/high bandwidth memory (HBM)) using thru-silicon-vias (TSV) or buried power rail (BPR). However, the conventional contact configuration limits the ability for high density connections in a stacked configuration.

Accordingly, there is a need for systems, apparatuses and methods that overcome the deficiencies of conventional designs including the methods, systems, and apparatuses for FinFET and Gate-All-Around (GAA) devices provided herein in the following disclosure.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus comprising a transistor includes a drain including a first drain silicide layer on a frontside surface of the drain and a second drain silicide layer on a backside surface of the drain, wherein at least one of the first drain silicide layer is coupled to a first drain contact structure or the second drain silicide layer is coupled to a second drain contact structure; a source including a first source silicide layer on a frontside surface of the source and a second source silicide layer on a backside surface of the source, wherein at least one of the first source silicide layer is coupled to a first source contact structure or the second source silicide layer is coupled to a second source contact structure; a gate structure disposed between the source and the drain; and a channel at least partially enclosed by the gate structure and disposed between the source and the drain, wherein the channel is recessed from the backside surface of the source and the backside surface of the drain.

In an aspect, an apparatus comprises a plurality of frontside lines; a plurality of backside lines; a first diffusion region extending in a first direction; a second diffusion region extending in the first direction; a plurality of gate structures offset from each other in the first direction and extending in a second direction perpendicular to the first direction; and a first transistor comprising: a first source and a first drain disposed in one of the first diffusion region and the second diffusion region; a first gate structure, disposed in one of the plurality of gate structures and disposed between the first source and the first drain; and a first channel, at least partially enclosed by the first gate structure, and disposed between the first source and the first drain, wherein the first channel is recessed from a backside surface of the first source and a backside surface of the first drain, and wherein at least one of the first gate structure, the first source, or the first drain is coupled to a first backside line of the plurality of backside lines.

In an aspect, a method for fabricating an apparatus including a transistor includes forming a drain including a first drain silicide layer on a frontside surface of the drain and a second drain silicide layer on a backside surface of the drain, wherein at least one of the first drain silicide layer is coupled to a first drain contact structure or the second drain silicide layer is coupled to a second drain contact structure; forming a source including a first source silicide layer on a frontside surface of the source and a second source silicide layer on a backside surface of the source, wherein at least one of the first source silicide layer is coupled to a first source contact structure or the second source silicide layer is coupled to a second source contact structure; forming a gate structure disposed between the source and the drain; and forming a channel at least partially enclosed by the gate structure and disposed between the source and the drain, wherein the channel is recessed from the backside surface of the source and the backside surface of the drain.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a partial top-down view of an apparatus in accordance with one or more aspects of the disclosure.

FIG. 1B illustrates a partial cross-sectional view of the apparatus of FIG. 1A in accordance with one or more aspects of the disclosure.

FIG. 1C illustrates a partial cross-sectional view of the apparatus of FIG. 1A in accordance with one or more aspects of the disclosure.

FIG. 1D illustrates a partial cross-sectional view of the apparatus of FIG. 1A in accordance with one or more aspects of the disclosure.

FIG. 2A illustrates a partial top-down view of an apparatus in accordance with one or more aspects of the disclosure.

FIG. 2B illustrates a partial cross-sectional view of the apparatus of FIG. 2A in accordance with one or more aspects of the disclosure.

FIG. 2C illustrates a partial cross-sectional view of the apparatus of FIG. 2A in accordance with one or more aspects of the disclosure.

FIG. 2D illustrates a partial cross-sectional view of the apparatus of FIG. 2A in accordance with one or more aspects of the disclosure.

FIG. 3 illustrates a partial cross-sectional view of an apparatus in accordance with one or more aspects of the disclosure.

FIGS. 4A-4H illustrate examples of stages of fabricating an integrated circuit structure in accordance with one or more aspects of the disclosure.

FIG. 5A illustrates a partial top-down view of an apparatus in accordance with one or more aspects of the disclosure.

FIG. 5B illustrates a partial cross-sectional view of the apparatus of FIG. 5A in accordance with one or more aspects of the disclosure.

FIG. 5C illustrates a partial cross-sectional view of the apparatus of FIG. 5A in accordance with one or more aspects of the disclosure.

FIG. 5D illustrates a partial cross-sectional view of the apparatus of FIG. 5A in accordance with one or more aspects of the disclosure.

FIG. 6A illustrates a partial top-down view of an apparatus in accordance with one or more aspects of the disclosure.

FIG. 6B illustrates a partial cross-sectional view of the apparatus of FIG. 6A in accordance with one or more aspects of the disclosure.

FIG. 6C illustrates a partial cross-sectional view of the apparatus of FIG. 6A in accordance with one or more aspects of the disclosure.

FIG. 6D illustrates a partial cross-sectional view of the apparatus of FIG. 6A in accordance with one or more aspects of the disclosure.

FIG. 7 illustrates a conventional standard cell.

FIG. 8A illustrates a standard cell in accordance with one or more aspects of the disclosure.

FIG. 8B illustrates a schematic of the standard cell in FIG. 8A in accordance with one or more aspects of the disclosure.

FIG. 9A illustrates a standard cell in accordance with one or more aspects of the disclosure.

FIG. 9B illustrates a schematic of the standard cell in FIG. 9A in accordance with one or more aspects of the disclosure.

FIG. 10A illustrates a standard cell in accordance with one or more aspects of the disclosure.

FIG. 10B illustrates a schematic of the standard cell in FIG. a0A in accordance with one or more aspects of the disclosure.

FIGS. 11A-11H illustrate examples of stages of fabricating an apparatus including transistors with double-side contacts in accordance with one or more aspects of the disclosure.

FIG. 12 illustrates components of an integrated device in accordance with one or more aspects of the disclosure.

FIG. 13A illustrates a flowchart of a method for manufacturing a device in accordance with one or more aspects of the disclosure.

FIG. 13B illustrates a flowchart of a method for manufacturing a device in accordance with one or more aspects of the disclosure.

FIG. 14 illustrates an exemplary mobile device in accordance with one or more aspects of the disclosure.

FIG. 15 illustrates various electronic devices that may be integrated with any of the devices disclosed in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

In certain described example implementations, instances are identified where various component structures and portions of operations can be taken from known, conventional techniques, and then arranged in accordance with one or more exemplary aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

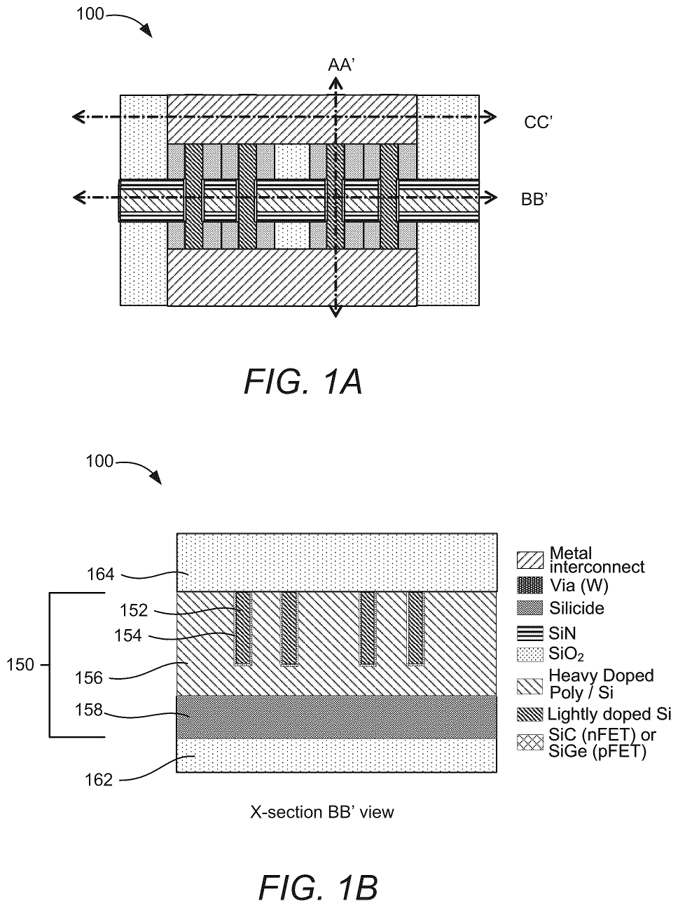

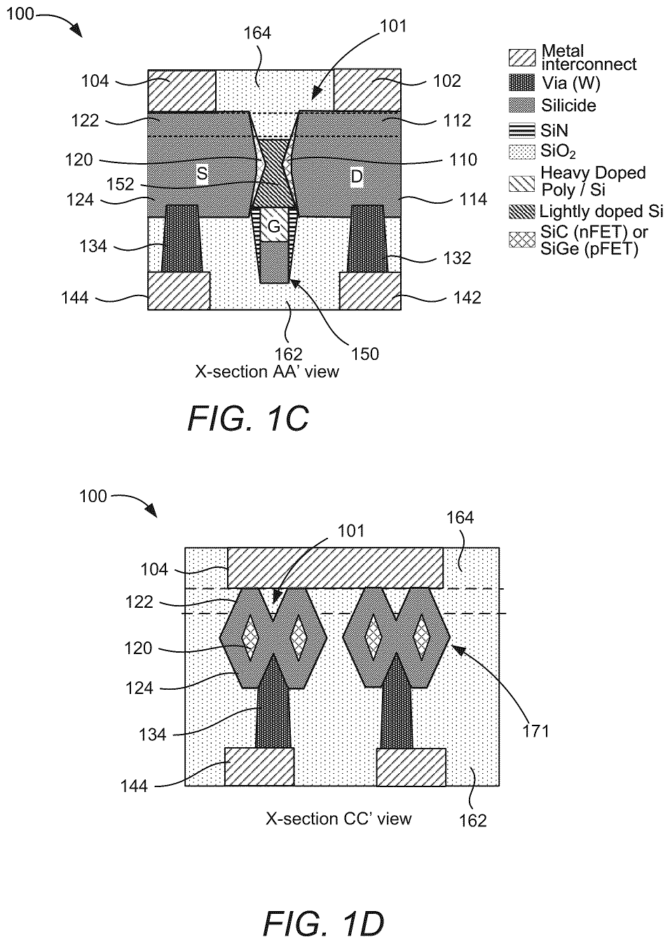

FIG. 1A illustrates a partial top-down view of an apparatus 100 in accordance with one or more aspects of the disclosure. The top-down view is of the wafer post flip. The apparatus, in some aspects, may be or include one or more three-dimensional integrated circuit (3DIC) devices. The top-down view illustrates a plurality of transistors in a cell configuration, with cross-sectional lines AA′, BB′ and CC′, which will be detailed in the following description.

FIG. 1B illustrates a partial cross-sectional view of the apparatus 100 of FIG. 1A in accordance with one or more aspects of the disclosure. Specifically, the cross-sectional view is illustrated along the BB′ line of FIG. 1A, which includes a plurality of gate structures 150. A gate poly 156 may be a heavily doped Polysilicon (Poly) and includes a plurality of channels 152, which in some aspects are a lightly doped Silicon (Si) and are surrounded by a gate oxide 154, which in some aspects is Silicon Dioxide (SiO₂). A gate contact layer 158, which in some aspects is silicide, is disposed on the gate poly 156. A frontside dielectric 162 is disposed on the plurality of gate structures 150 and backside dielectric 164 is disposed on an opposite side of the plurality of gate structures 150.

FIG. 1C illustrates a partial cross-sectional view of the apparatus 100 of FIG. 1A in accordance with one or more aspects of the disclosure. Specifically, the cross-sectional view is illustrated along the AA′ line of FIG. 1A. The apparatus 100 includes a transistor 101 that has a drain 110 substantially enclosed in a drain silicide layer 114 (e.g., in some aspects only a portion of the source adjacent the channel 152 is exposed). An integral drain via portion 112 of the drain silicide layer 114 is coupled to a second drain contact 102 (which is a metal interconnect and part of a backside metallization structure discussed in further detail below). A first drain via 132 couples the drain silicide layer 114 to a first drain contact 142 (which is part of a frontside metallization structure discussed in further detail below). A source 120 is substantially enclosed in a source silicide layer 124. An integral source via portion 122 of the source silicide layer 124 is coupled to a second source contact 104 (which is part of a backside metallization structure discussed in further detail below). A first source via 134 couples the source silicide layer 124 to a first source contact 144 (which is part of a frontside metallization structure discussed in further detail below). A gate structure 150 is disposed between the source 120 and the drain 110. The frontside dielectric 162 is disposed on the frontside of transistor 101 and the backside dielectric 164 is disposed on an opposite side of the transistor 101. In some aspects, a thickness (indicated by the dashed lines) of the integral drain via portion (112) and the integral source via portion (122) are each on the order of 5 nm to 40 nm. In some aspects, the integral source via portion 122 is in direct contact with the second source contact 104 and the integral drain via portion 112 is in direct contact with the second drain contact 102. In some aspects, the drain silicide layer 114 and source silicide layer 124 each have a substantially uniform thickness. In some aspects, the drain silicide layer 114 and source silicide layer 124 have substantially a same thickness. In some aspects, the integral drain via portion 112 is embedded in the drain silicide 114 and the drain 110 (e.g., the integral drain via portion 112 is formed as part of the drain layer). In some aspects, the integral drain via portion 112 is an extended portion of the drain silicide 114 and the drain 110 (e.g., the integral drain via portion 112 is formed as an additional portion to the drain layer).

FIG. 1D illustrates a partial cross-sectional view of the apparatus 100 of FIG. 1A in accordance with one or more aspects of the disclosure. Specifically, the cross-sectional view is illustrated along the CC′ line of FIG. 1A. The apparatus 100 includes a transistor 101 that has a drain 110, where the source 120 is substantially enclosed in a source silicide layer 124. An integral source via portion 122 of the source silicide layer 124 is coupled to a second source contact 104 (which is part of a backside metallization structure discussed in further detail below). A first source via 134 couples the source silicide layer 124 to a first source contact 144 (which is part of a frontside metallization structure discussed in further detail below). In some aspects, the integral source via portion 122 is embedded in the source silicide 124 and the source 120 (e.g., the integral source via portion 122 is formed as part of the source layer). In some aspects, the integral source via portion 122 is an extended portion of the source silicide 124 and the source 120 (e.g., the integral source via portion 122 is formed as an additional portion to the source layer). The frontside dielectric 162 is disposed on the frontside of transistor 101 and the backside dielectric 164 is disposed on an opposite side of the transistor 101, however, in some portions the frontside dielectric 162 and the backside dielectric 164 may form a generally homogeneous dielectric portion enclosing the transistor 101 and other transistors of the apparatus 100. A portion of another transistor 171 is illustrated and has similar features as transistor 101, so details will not be provided.

In some aspects, the drain 110 and the source 120 may be formed from one of Silicon or Carbon doped Silicon, e.g., for NFETs, or Silicon Germanium (SiGE), e.g., for PFETs. In some aspects, the second source contact 104, second drain contact 102, first drain contact 142, and first source contact 144 are formed from one or more of tungsten (W), copper (Cu), palladium (Pd), nickel (Ni), gold (Au), tantalum (Ta), tantalum nitride (TaN), titanium (Ti), titanium nitride (TiN), bismuth (Bi), antimony (Sb), molybdenum (Mo), and ruthenium (Ru) or any highly conductive material. In some aspects, the first drain via 132 and first source via 134 are formed of tungsten (W) or any highly conductive material.

It will be appreciated that in the various aspects disclosed, the transistors (e.g., 101, 171) of apparatus 100 can be electrically connected on a first side (frontside) and/or second side (backside) to the source and drain. Further, it will be appreciated that although capable of being electrically connected on both sides, in some aspects, the source and/or drain may only be connected on one side. For example, the source and drain of transistor 101 may be connected on the frontside and the drain and source of transistor 171 may only be connected on the backside. Further, it will be appreciated that the capability of having frontside and/or backside contacts to form frontside and/or backside connections allows for improved standard cell configurations, which are discussed in subsequent portions of this disclosure.

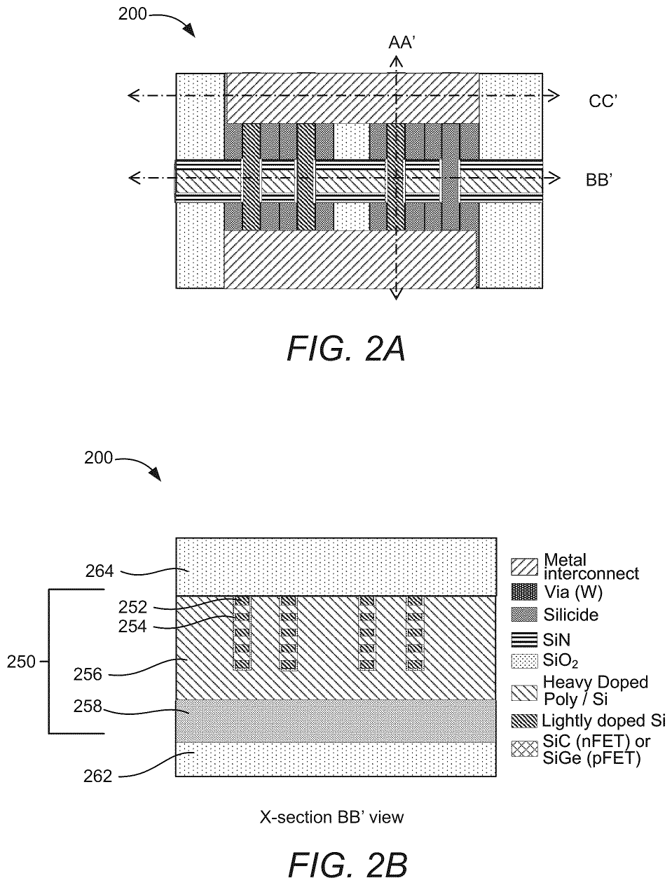

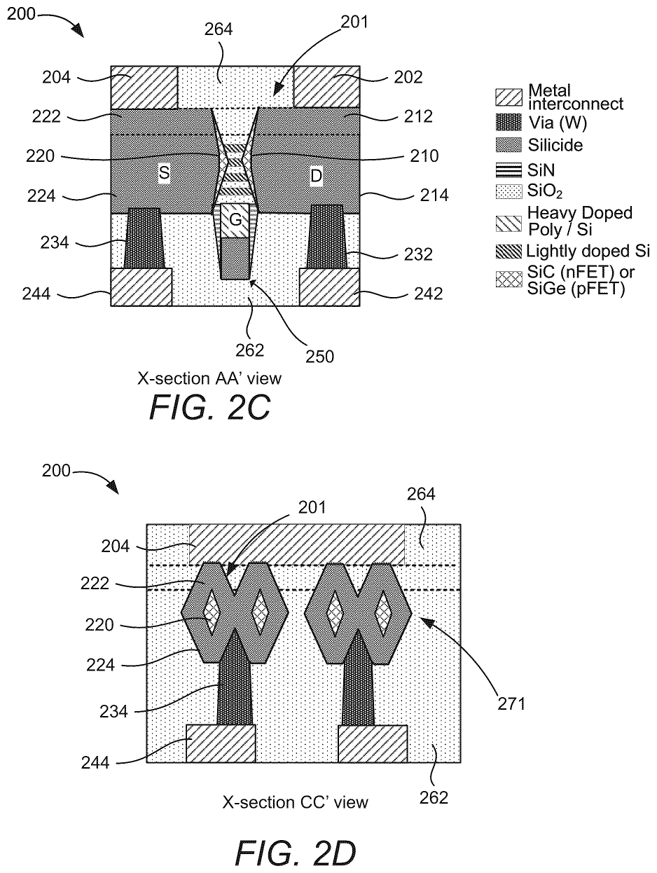

FIG. 2A illustrates a partial top-down view of an apparatus 200 in accordance with one or more aspects of the disclosure. The top-down view is a view of the wafer post flip. The apparatus, in some aspects, may be or include one or more three-dimensional integrated circuit (3DIC) devices, including Gate-All-Around (GAA) devices. The top-down view illustrates a plurality of transistors in a cell configuration, with cross-sectional lines AA′, BB′ and CC′, which will be detailed in the following description.

FIG. 2B illustrates a partial cross-sectional view of the apparatus 200 of FIG. 2A in accordance with one or more aspects of the disclosure. Specifically, the cross-sectional view is illustrated along the BB′ line of FIG. 2A, which includes a plurality of gate structures 250. A gate poly 256 may be a heavily doped Polysilicon (Poly) and includes a plurality of gate stack portions 252, which in some aspects are a lightly doped Si and are surrounded by a gate oxide 254, which in some aspects is Silicon Dioxide (SiO₂). A gate contact layer 258, which in some aspects is silicide, is disposed on the gate poly 256.

A frontside dielectric 262 is disposed on the plurality of gate structures 250 and backside dielectric 264 is disposed on an opposite side of the plurality of gate structures 250. It will be appreciated that the gate structure 250 was presented in a simplified version and is not limited to the illustrated configurations and may use any conventional gate configurations. For example, the gate structure 250 may include a metal gate surrounding a nanowire or nanosheet (e.g., silicon sheets horizontally stacked) configuration including a high-k metal gate filling the space between the silicon channels and inner spacers for gate to source-drain isolation and may be formed using a replacement metal gate (RMG) process or other conventional fabrication processes, as is known in the art.

FIG. 2C illustrates a partial cross-sectional view of the apparatus 200 of FIG. 2A in accordance with one or more aspects of the disclosure. Specifically, the cross-sectional view is illustrated along the AA′ line of FIG. 2A. The apparatus 200 includes a transistor 201 that has a drain 210 substantially enclosed in a drain silicide layer 214. An integral drain via portion 212 of the drain silicide layer 214 is coupled to a second drain contact 202 (which is a metal interconnect and part of a backside metallization structure discussed in further detail below). A first drain via 232 couples the drain silicide layer 214 to a first drain contact 242 (which is part of a frontside metallization structure discussed in further detail below). A source 220 is substantially enclosed in a source silicide layer 224. An integral source via portion 222 of the source silicide layer 224 is coupled to a second source contact 204 (which is part of a backside metallization structure discussed in further detail below). A first source via 234 couples the source silicide layer 224 to a first source contact 244 (which is part of a frontside metallization structure discussed in further detail below). A gate structure 250 is disposed between the source 220 and the drain 210. The frontside dielectric 262 is disposed on the frontside of transistor 201 and the backside dielectric 264 is disposed on an opposite side of the transistor 201. In some aspects, the integral source via portion 222 is in direct contact with the second source contact 204 and the integral drain via portion 212 is in direct contact with the second drain contact 202. In some aspects, the drain silicide layer 214 and source silicide layer 224 each have a substantially uniform thickness. In some aspects, the drain silicide layer 214 and source silicide layer 224 have substantially a same thickness. In some aspects, the integral drain via portion 212 is embedded in the drain silicide 214 and the drain 210. In some aspects, the integral drain via portion 212 is an extended portion of the drain silicide 214 and the drain 210.

FIG. 2D illustrates a partial cross-sectional view of the apparatus 200 of FIG. 2A in accordance with one or more aspects of the disclosure. Specifically, the cross-sectional view is illustrated along the CC′ line of FIG. 2A. The apparatus 200 includes a transistor 201 where the source 220 is substantially enclosed in a source silicide layer 224. An integral source via portion 222 of the source silicide layer 224 is coupled to a second source contact 204 (which is part of a backside metallization structure discussed in further detail below). A first source via 234 couples the source silicide layer 224 to a first source contact 244 (which is part of a frontside metallization structure discussed in further detail below). In some aspects, the integral source via portion 222 is embedded in the source silicide 224 and the source 220. In some aspects, the integral source via portion 222 is an extended portion of the source silicide 224 and the source 220. The frontside dielectric 262 is disposed on the frontside of transistor 201 and the backside dielectric 264 is disposed on an opposite side of the transistor 201. The frontside dielectric 262 is disposed on the frontside of transistor 201 and the backside dielectric 264 is disposed on an opposite side of the transistor 201, however, in some portions the frontside dielectric 262 and the backside dielectric 264 may form a generally homogeneous dielectric portion enclosing the transistor 201 and other transistors of the apparatus 200.

In some aspects, the drain 210 and the source 220 may be formed from one of Carbon doped Silicon, e.g., for NFETs, or Silicon Germanium (SiGE), e.g., for PFETs. In some aspects, the second source contact 204, second drain contact 202, first drain contact 242, and first source contact 244 are formed from one or more of tungsten (W), copper (Cu), palladium (Pd), nickel (Ni), gold (Au), tantalum (Ta), tantalum nitride (TaN), titanium (Ti), titanium nitride (TiN), bismuth (Bi), antimony (Sb), molybdenum (Mo), and ruthenium (Ru) or any highly conductive material. In some aspects, the first drain via 232 and first source via 234 are formed of tungsten (W) or any highly conductive material.

It will be appreciated that in the various aspects disclosed, the transistors (e.g., 201, 271) of apparatus 200 can be electrically connected on a first side (frontside) and/or second side (backside) to the source and drain. Further, it will be appreciated that although capable of being electrically connected on both sides, in some aspects, the source and/or drain may only be connected on one side. For example, the source and drain of transistor 201 may be connected on the frontside and the drain and source of transistor 271 may only be connected on the backside. Further, it will be appreciated that the capability of having frontside and/or backside contacts to form frontside and/or backside connections allows for improved standard cell configurations, which are discussed in subsequent portions of this disclosure.

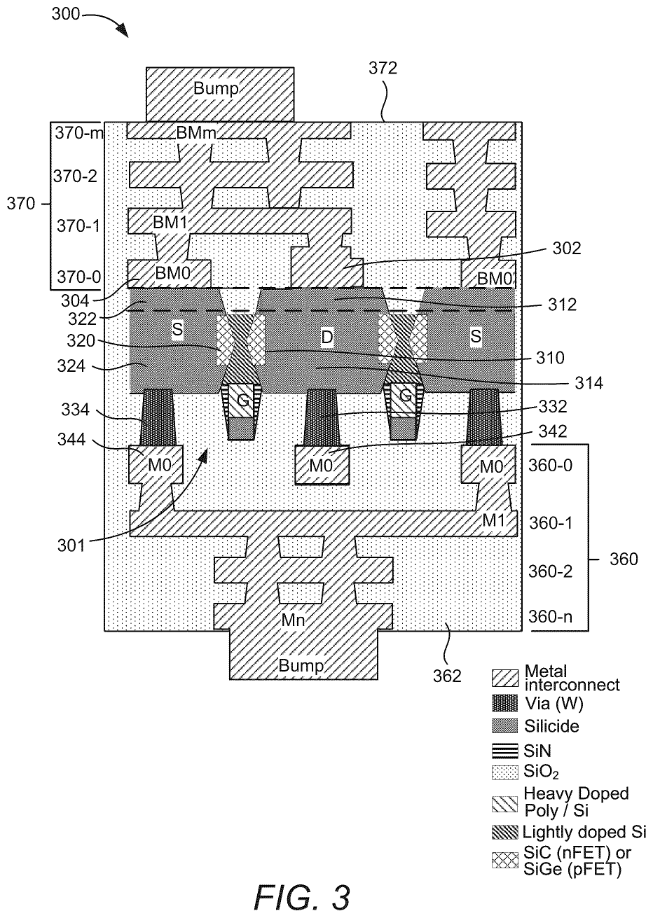

FIG. 3 illustrates a partial cross-sectional view of an apparatus 300 in accordance with one or more aspects of the disclosure. The apparatus 300 includes a transistor 301, similar to the transistors (e.g., 101, 201, 501, 601, etc.) discussed in the foregoing and following paragraphs. Accordingly, details of the transistor 301 structure will not be specifically labeled or provided. As discussed in relation to the prior transistors, the transistor 301 has a drain 310 substantially enclosed in a drain silicide layer 314 and a source 320 is substantially enclosed in a source silicide layer 324. An integral drain via portion 312 of the drain silicide layer 314 is coupled to a second drain contact 302 which is part of a backside metallization 370 structure, specifically, metal layer 370-0 (BMO). An integral source via portion 322 of the source silicide layer 324 is coupled to a second source contact 304 which is also part of the backside metallization 370 structure, specifically, metal layer 370-0 (BMO). A first drain via 332 couples the drain silicide layer 314 to a first drain contact 342, which is part of a frontside metallization structure 360, specifically, metal layer 360-0 (M0). A first source via 334 couples the source silicide layer 324 to a first source contact 344 which is also part of the frontside metallization structure 360, specifically, metal layer 360-0 (M0). Frontside metal layers 360-0, 360-1, 360-2, 360-n are formed in the frontside dielectric 362. The frontside dielectric 362 provides insulation for the frontside metallization structure 360. Backside metal layers 370-0, 370-1, 370-2, 370-m are formed in the frontside dielectric 372. The backside dielectric 372 provides insulation for the backside metallization structure 370.

It will be appreciated that in the various aspects disclosed, the frontside metallization structure 360 and the backside metallization structure 370 may be coupled to different frontside and backside contact structures (e.g., direct to silicide, silicide to contact, silicide to contact to via, or silicide to via) as disclosed herein. For example, vias may be used to couple to one or both of the frontside metallization structure 360 or the backside metallization structure 370. Further, it will be appreciated that although capable of being electrically connected on both sides, in some aspects, the gate, source and/or drain may only be connected on one side, as discussed herein. Accordingly, the various aspects disclosed are not limited to the example illustrations provided.

It will be appreciated that a reduction in the IC thickness can be achieved by directly coupling the integral drain via portion 312 to the second drain contact 302, and the integral source via portion 322 to the second source contact 304, which both are part of the backside metallization 370 structure. Additionally, the connectivity of local devices and 3DIC performance can be improved. For example, multiple ICs can be stacked to provide an increased functionality and a smaller form factor. In some aspects, the integral drain via portion 312 and/or the integral source via portion 322 may be coupled directly to a buried power rail (BPR). In this configuration, limitations of conventional microscopic thru-silicon-vias (mTSV) coupling are eliminated. Further, the integral drain via portion 312 and integral source via portion 322 allow for back side interconnections and can be directly used to connect power rails similar to BPR. However, unlike BPR, the integral drain via portions 312/integral source via portions 322 do not need any additional area outside of the active device, which provides more flexibility for the connections and are not limited to power or ground nets. Additionally, it will be appreciated that the capability of having frontside and/or backside contacts to form frontside and/or backside connections allows for improved standard cell configurations (e.g., reduced cell height), which are discussed in subsequent portions of this disclosure.

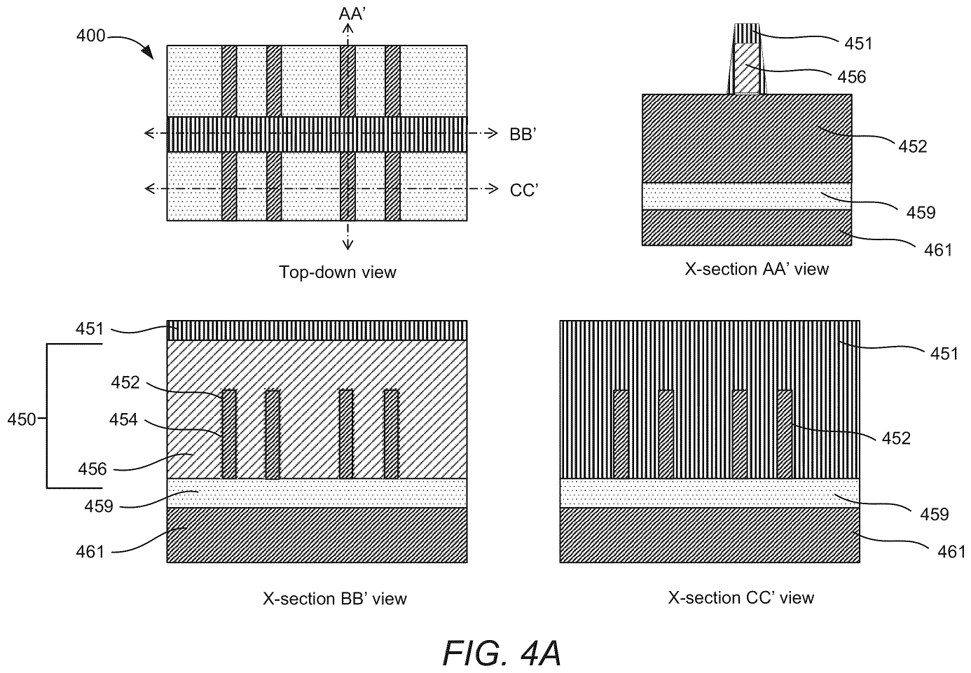

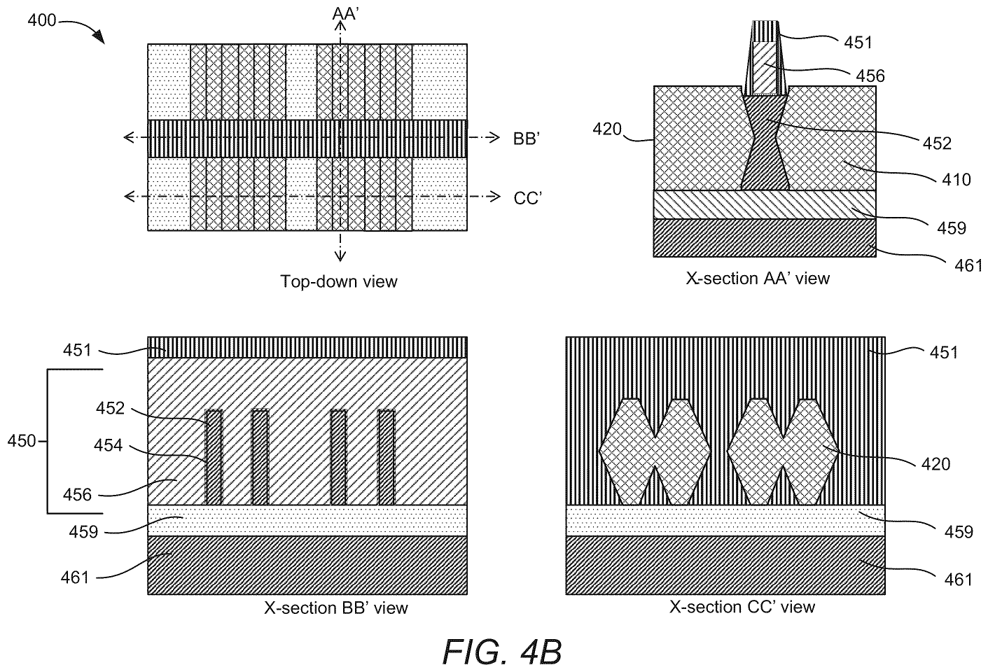

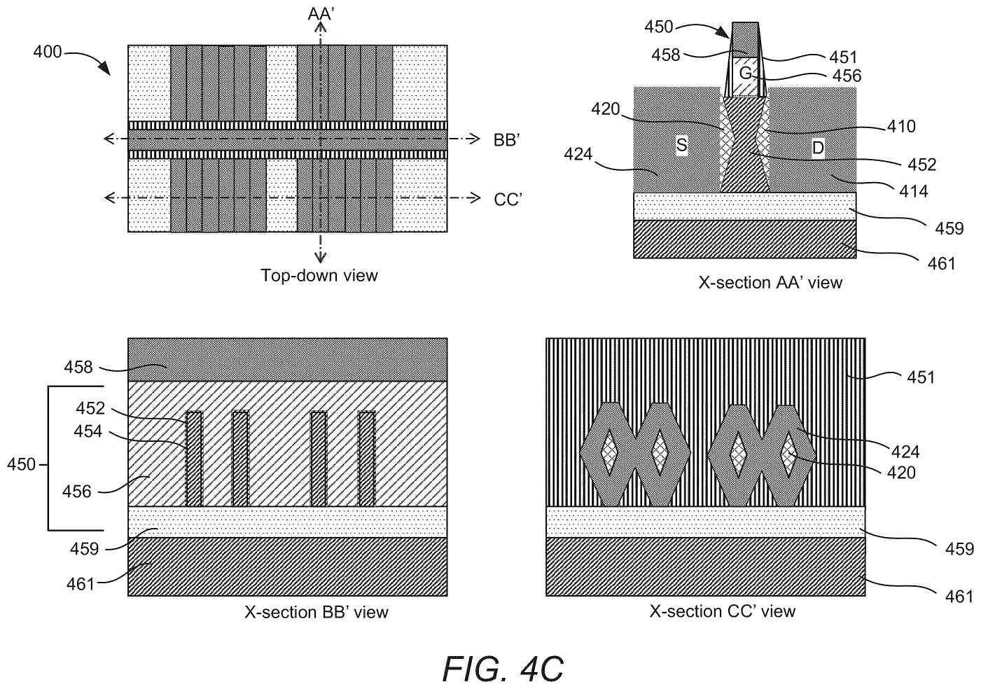

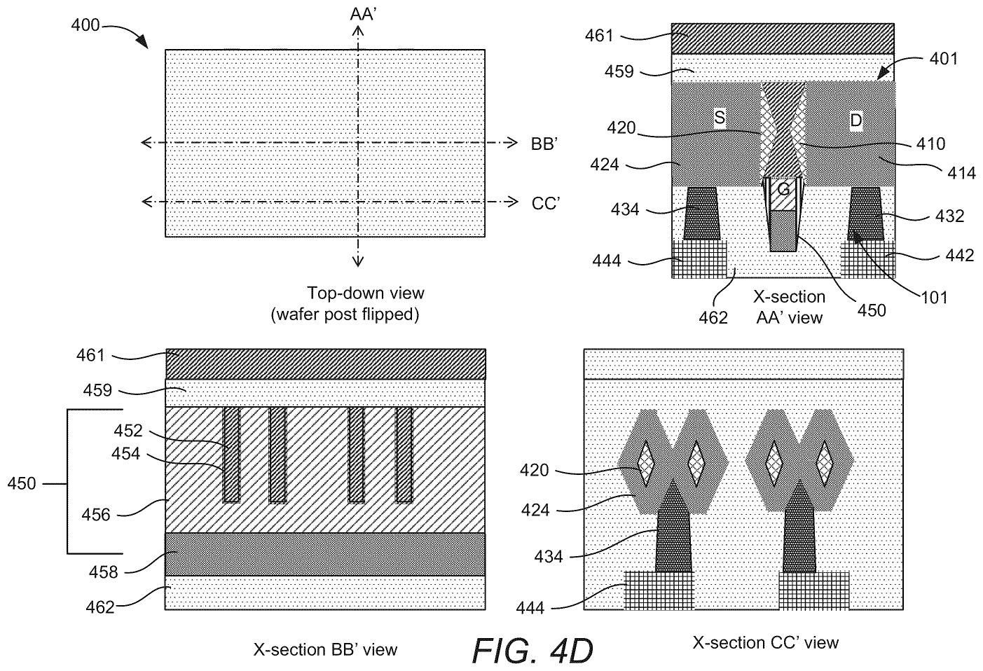

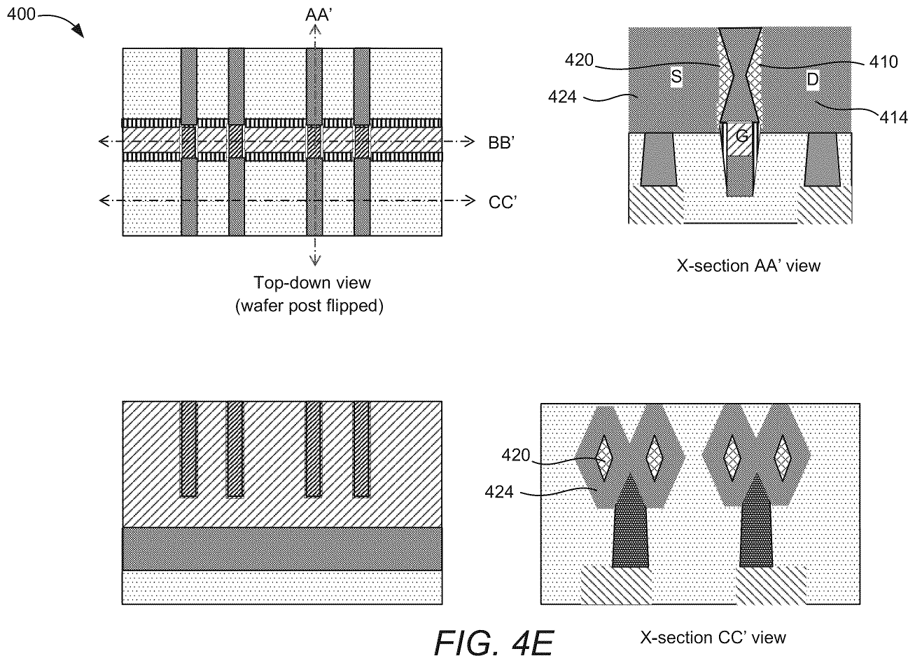

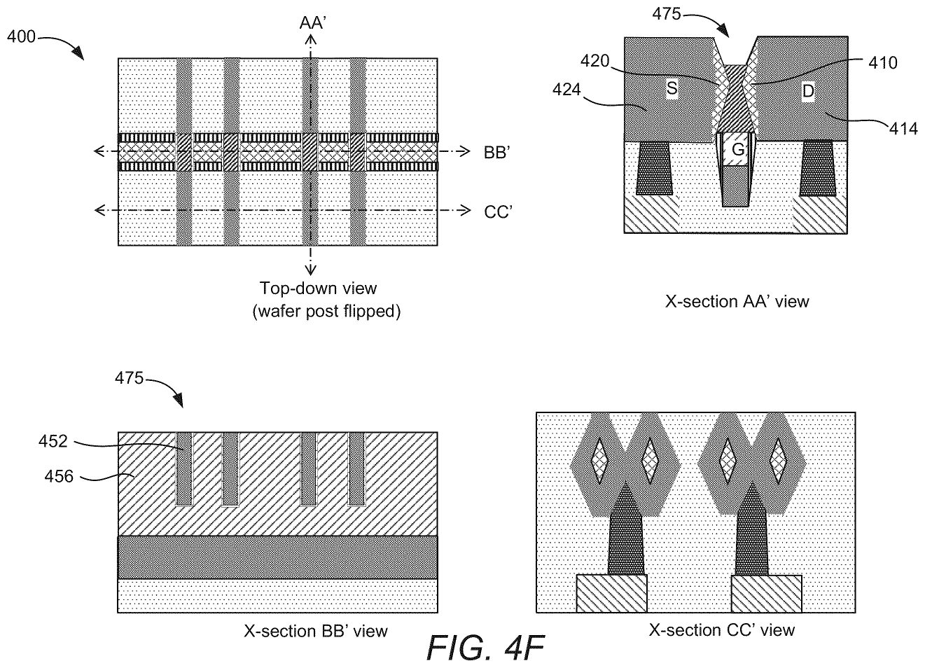

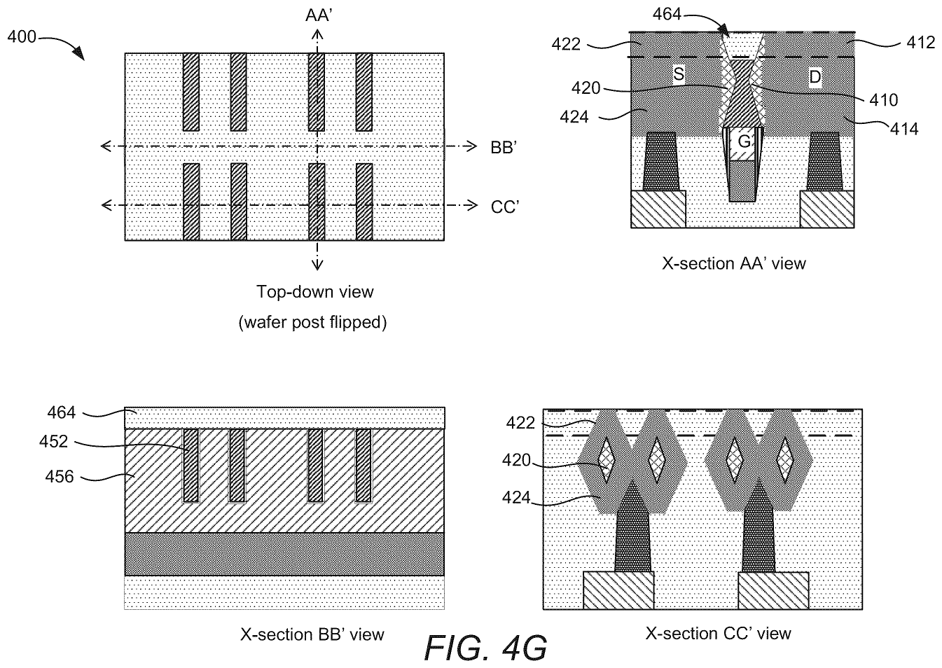

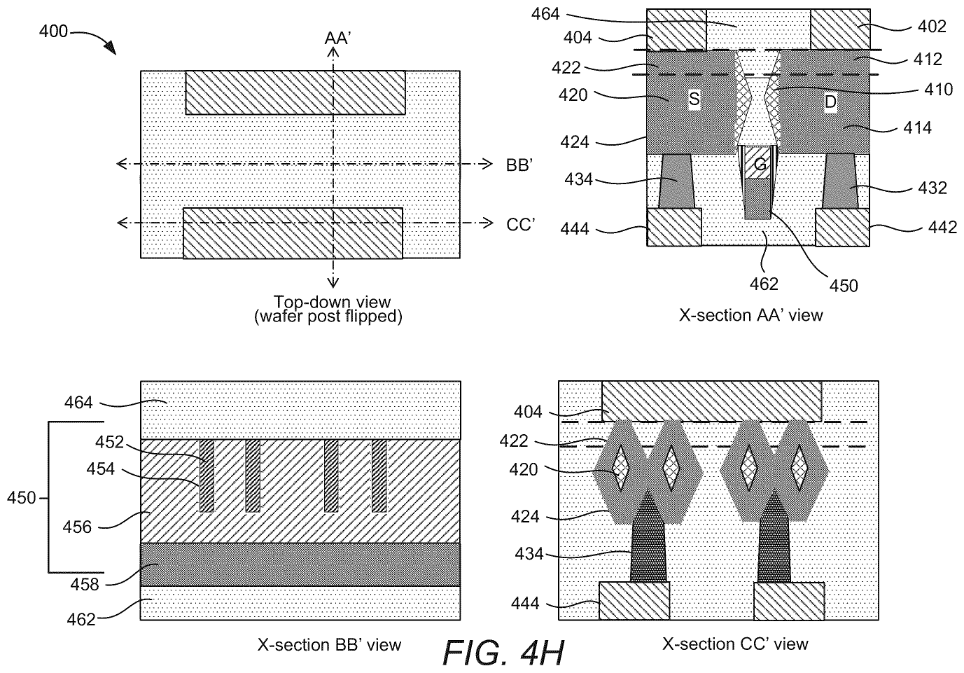

FIGS. 4A-4H illustrate examples of stages of fabricating an integrated circuit structure in accordance with one or more aspects of the disclosure. In this instance, the stages may apply to the fabrication of an apparatus 400 similar to the foregoing apparatuses 100, 200 and 300.

FIG. 4A illustrates a portion of a fabrication process of an apparatus 400 in accordance with one or more aspects of the disclosure. In the illustration, a plan view and three cross-sectional views are provided. The cross-sectional views are along the AA′, BB′ and CC′ lines of the plan view, which is a top-down view. At this stage of the fabrication process, the channels 452 and the gate spacer 451 are formed. Specifically, the cross-sectional view is illustrated along the BB′ line and includes a plurality of gate structures 450. A gate poly 256 may be a heavily doped Polysilicon (Poly) and includes a plurality of channels 452, which in some aspects are a lightly doped Si and are surrounded by a gate oxide 454, which in some aspects is Silicon Dioxide (SiO₂). A buried oxide layer 459, which in some aspects is SiO₂, is disposed on a substrate 461, which in some aspects is a lightly doped Si. The cross-sectional view illustrated along the AA′ line and the cross-sectional view illustrated along the CC′ line (along the source/drain (S/D) region) each includes similar elements viewed from the illustrated perspective.

FIG. 4B illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a top-down view. At this stage of the fabrication process, the sources/drains are formed. The source 420/drain 410 (S/D) may be formed by epitaxial (epi) techniques that are commonly employed. Epitaxy involves the growth of a crystalline material (e.g., using Carbon doped Silicon or SiGe) on the surface of the channels 452, to reduce parasitic series resistance. The cross-sectional view illustrated along the AA′ line includes a source 420 and a drain 410 with a gate structure 450, including the channel 452, gate poly 456 and channel 452. The buried oxide layer 459 between the substrate 461, The cross-sectional view illustrated along the CC′ line (along the source/drain region, as each will have a similar structure) each source 420 (and drain), in some aspects has a generally diamond shape in this perspective view. The cross-sectional view illustrated along the BB′ line (channel portion) includes a plurality of gate structures 450, which includes a gate poly 456, including a plurality of channels 452, a gate oxide 454, which in some aspects is SiO₂. The cross-sectional view illustrated along the BB′ line is unchanged from FIG. 4A, so a detailed rendition of all the elements will not be presented.

FIG. 4C illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a top-down view. At this stage of the fabrication process, silicide is disposed over the source/drain portions. The cross-sectional view illustrated along the AA′ line includes the source 420 substantially enclosed by source silicide layer 424 and the drain 410 substantially enclosed by drain silicide layer 414. The gate structure 450 also has a portion of the gate poly 456 removed and replaced by gate contact layer 458 opposite the channel 452. The buried oxide layer 459 is disposed between silicide layers 414, 424, and the substrate 461. The cross-sectional view illustrated along the CC′ line (along the source region) includes a plurality of source structures, each source 420, in some aspects has a diamond shape in this perspective view and is enclosed by source silicide layer 424. The silicide layers 414 and 424 may also have a diamond shape, as in some aspects the silicide layers 414 and 424 have a uniform thickness and may also have the same thickness. The cross-sectional view illustrated along the BB′ line (channel portion) includes a plurality of gate structures 450, which includes a gate poly 456, including a plurality of channels 452, and a gate oxide 454. The cross-sectional view illustrated along the BB′ line is unchanged from FIG. 4A, except for the silicide forming the gate contact layer 458, so a detailed rendition of all the elements will not be presented.

FIG. 4D illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a flipped top-down view. At this stage of the fabrication process, one or more frontside metal layers may be formed, including the first drain contact 442, first drain via 432, first source via 434 and first source contact 444. This may be accomplished through standard CMOS front-end-of-line (FEOL), middle-of-line (MOL) or middle-end-of-line (MEOL), and back-end-of-line (BEOL) processes. Additionally, after the BEOL processing the wafer is flipped so the top view is from the flipped perspective. The cross-sectional view illustrated along the AA′ line includes the source 420 substantially enclosed by source silicide layer 424, which is coupled to the first source via 434 and first source contact 444. The drain 410 is substantially enclosed by drain silicide layer 414, which is coupled to the first drain via 432 and first drain contact 442. The frontside dielectric 462 is disposed on the frontside of transistor 401.

The cross-sectional view illustrated along the CC′ line (along the source region) includes a plurality of source structures, each source 420, in some aspects has a diamond shape in this perspective view and is enclosed by source silicide layer 424 which is coupled to the first source via 434 and first source contact 444. The cross-sectional view illustrated along the BB′ line (channel portion) includes a plurality of gate structures 450, which includes a gate poly 456, and each including a channel 452, a gate oxide 454. the gate contact layer 458 is disposed between the gate poly 456 and frontside dielectric 462. Since the wafer has been flipped the substrate 461 and buried oxide layer 459 are now illustrated on the top.

FIG. 4E illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a flipped top-down view. At this stage of the fabrication process, the substrate and buried oxide layer are removed which exposes the bottom side of the source 420, source silicide layer 424, drain 410 and drain silicide layer 414 for further processing. Since no other changes were made at this stage, further details of the cross-sectional views along the AA′, BB′ and CC′ lines will not be provided.

FIG. 4F illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a flipped top-down view. At this stage of the fabrication process, the selective etching is used to remove the silicon from a portion of the channel 452 and poly (gate poly 456) but retains the silicide. This forms a recess 475 in the channel region, between the source 420, source silicide layer 424, drain 410 and drain silicide layer 414. Since no other changes were made at this stage, further details of the cross-sectional views along the AA′, BB′ and CC′ lines will not be provided.

FIG. 4G illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a flipped top-down view. At this stage of the fabrication process, a backside dielectric layer is deposited, and a chemical mechanical polishing (CMP) is performed to expose the source 420 enclosed in source silicide layer 424 and drain 410 enclosed in drain silicide layer 414. Additionally, the CMP provides for a smooth planar surface on backside dielectric 464, source silicide layer 424 and drain silicide layer 414. In particular, the CMP provides a smooth contact surface for integral source via portion 422 of the source silicide layer 424 and integral drain via portion 412 of the drain silicide layer 414 for further processing. It will be appreciated that in some aspects, the integral drain via portion 412 may be embedded, e.g., formed as part of the drain silicide layer 414 or in other aspects, the integral drain via portion 412 may be extended, e.g., formed as an additional portion/layer of the drain silicide layer 414. Likewise, it will be appreciated that in some aspects, the integral source via portion 422 may be embedded, e.g., formed as part of the source silicide layer 424 or in other aspects, the integral source via portion 422 may be extended, e.g., formed as an additional portion/layer of the source silicide layer 424. Since no other changes were made at this stage, further details of the cross-sectional views along the AA′, BB′ and CC′ lines will not be provided.

FIG. 4H illustrates a portion of a fabrication process of the apparatus 400 in accordance with one or more aspects of the disclosure. In the illustration, a plan view and three cross-sectional views are provided. The cross-sectional views are along the AA′, BB′ and CC′ lines of the plan view, which is a flipped top-down view. At this stage of the fabrication process, BEOL processing is performed on the backside of the apparatus 400. The BEOL processing is used to form a second drain contact 402 directly on the integral drain via portion 412 of the drain silicide layer 414 and a second source contact 404 directly on the integral source via portion 422 of the source silicide layer 424. The integral via portions 412 and 422 allow for improved tolerance for overlapping or underlapping between the integral via portions 412 and 422 and metal routing (e.g., contacts 102 and 104). As part of BEOL processing on the backside, backside dielectric 464 is disposed over the contacts and additional metal layers of the backside (note the additional metal layers are not illustrated). Since no other changes were made at this stage, further details of the cross-sectional views along the AA′, BB′ and CC′ lines, will not be provided, however, the various elements are labeled consistently with the foregoing elements.

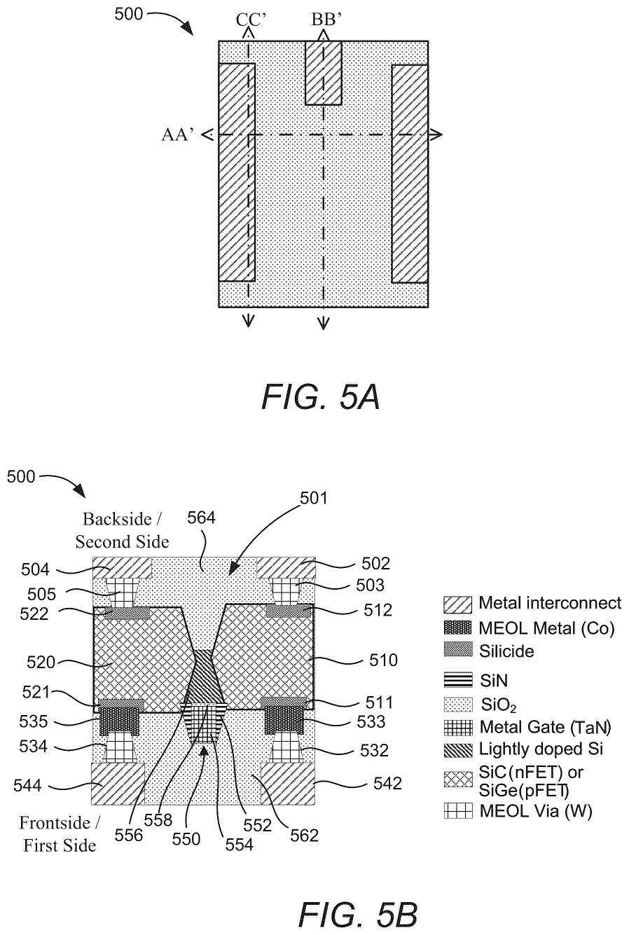

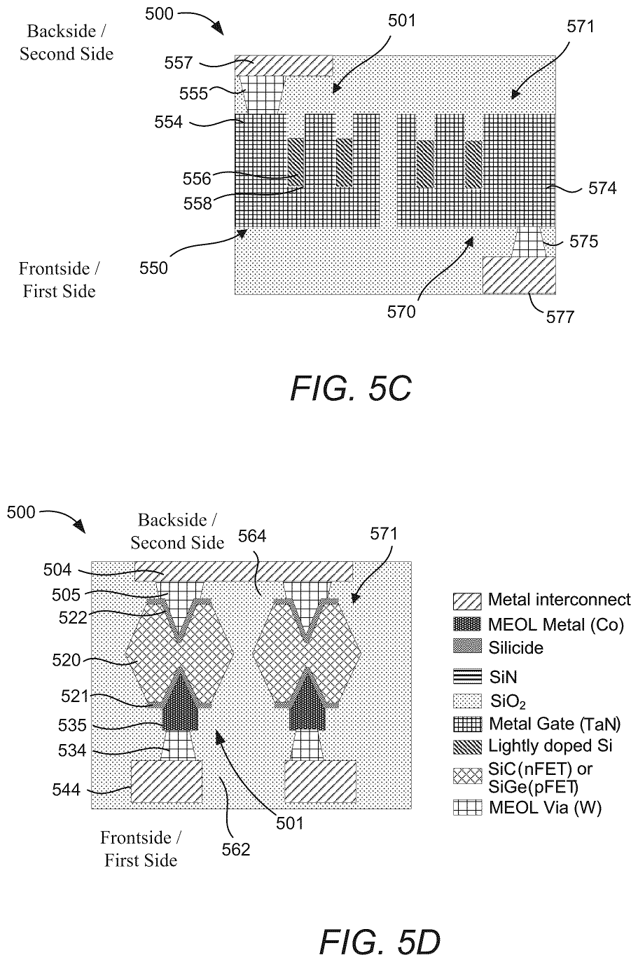

FIGS. 5A to 5D illustrate portions of an apparatus 500 including transistors with double-side contacts (contact structures)/dual-side contacts (contact structures) for the gate, source, and drain, which allows for electrical connection accessibility from both sides of the transistors and the silicon wafer. In contrast, the MEOL and FEOL processes in conventional devices are restricted to connections on the frontside of the silicon wafer. Interconnect routing becomes too crowded and limits further area-scaling of the standard cells. Aspects of the disclosure can improve the porosity (e.g., contact connection opportunities) and significantly decreases the area of standard cells including apparatus 500 according to various aspects of the disclosure.

FIG. 5A illustrates a top-down view of an apparatus 500 including a plurality of transistors in a cell configuration with various cut lines for cross-sectional views along cut lines AA′, BB′ and CC′, in subsequent FIGS. 5B, 5C and 5D. It will be appreciated that apparatus 500 may include more transistors and associated conductive structures and interconnections between transistors within apparatus 500 and/or to external devices.

FIG. 5B illustrates a cross-sectional portion of an apparatus 500 including FinFET transistor 501 along line AA′, as illustrated in FIG. 5A. A gate structure 550 is disposed between a drain 510 and source 520. The gate structure 550 can include outer spacers 552, which in some aspects may be Silicon Nitride (SiN) or any suitable dielectric, metal gate 554, which in some aspects may be TaN or any suitable conductor and a gate oxide 558, to separate the metal gate 554 from the channel 556. In some aspects the gate oxide 558 may be SiO₂ or similar materials. In some aspects, gate oxide 558 may be a high dielectric constant (high-k or HK) material, such as hafnium dioxide (HfO₂). titanium dioxide (TiO₂) or other materials that have k values higher than 3.9. The channel 556, which in some aspects may be Si, is at least partially enclosed by the gate structure 550 and in some aspects is enclosed on three sides as illustrated. It will be appreciated that the channel 556 is recessed relative to the drain 510 and the source 520. In some aspects, the channel recess can be in the range of 5 nm to 50 nm. The drain 510 may include a first drain silicide layer 511 on a first side (frontside) of the transistor 501 and a second drain silicide layer 512 on a second side (backside) of the transistor 501. The first drain silicide layer 511 is coupled to a first drain contact 533 (which in some aspects may be Co and may be formed in the MEOL) that is coupled to a first drain via 532 (which in some aspects may be W and may be formed in the MEOL). The first drain silicide layer 511, first drain via 532 and first drain contact 533 may generally be referred to as a first contact structure or frontside contact structure, as it will be appreciated that the electrical coupling on the frontside between the drain and the frontside metallization structure may include different configurations. The first drain via 532 is coupled to a first drain connection portion 542 (which is part of a frontside metallization structure, as discussed herein). The second drain silicide layer 512 is coupled to a second drain via 503. The second drain via 503 is coupled to a second drain connection portion 502 (which is part of a backside metallization structure, as discussed herein). The second drain silicide layer 512 and second drain via 503 may generally be referred to as a second contact structure or backside contact structure, as it will be appreciated that the electrical coupling on the backside between the drain and the backside metallization structure may include different configurations.

The source 520 may include a first source silicide layer 521 on a first side of the transistor 501 and a second source silicide layer 522 on a second side of the transistor 501. The first source silicide layer 521 is coupled to a first source contact 535 (which in some aspects may be Co and may be formed in the MEOL) that is coupled to a first source via 534 (which in some aspects may be W and may be formed in the MEOL). The first source via 534 is coupled to a first source connection portion 544 (which is part of a frontside metallization structure, as discussed herein). The first source contact 535 and first source via 534 may also generally be referred to as a first contact structure or frontside contact structure, as it will be appreciated that the electrical coupling on the frontside between the source and the frontside metallization structure may include different configurations. The second source silicide layer 522 is coupled to a second source via 505 (which in some aspects may be W and may be formed in the MEOL). The second source via 505 is coupled to a second source connection portion 504 (which is part of a backside metallization structure, as discussed herein). The second source via 504 may also generally be referred to as a second contact structure or backside contact structure, as it will be appreciated that the electrical coupling on the backside between the source and the backside metallization structure may include different configurations.

Further, it will be appreciated that for various aspects, the source/drain (S/D) may be used as a general reference for various transistor configurations, where the specific source and/or drain is not specifically identified as a source or drain. Accordingly, the second or backside contact structure, as used herein can be used for either the source or drain connection to the backside metallization structure (e.g., at BMO). Likewise, the first or frontside contact structure, as used herein can be used for either the source or drain connection to the frontside metallization structure (e.g., at M0). Further, the foregoing example illustration includes connections on both sides of each of the source and drain, as an illustration of the possible frontside and backside connection opportunities. However, it will be appreciated that the various aspects are not limited to the example illustrations provided and various aspects may include connections on only one side of the source and/or drain.

FIG. 5C illustrates a partial cross-sectional view of the apparatus 500 of FIG. 5A in accordance with one or more aspects of the disclosure. Specifically, the cross-sectional view is illustrated along the BB′ line of FIG. 5A. The apparatus 500 includes a transistor 501 that has the gate structure 550 as discussed above and a second transistor 571 with a second gate structure 570, which is similar to gate structure 550, so a detailed explanation will not be provided. Additionally, it will be appreciated that the channel 556 is recessed from the backside surface of the gate structure 550, which can be seen from this view. Gate structure 550 has the metal gate 554 coupled to a first gate contact 555 (e.g., a MEOL via or other conductive structure, which in some aspects may be W). The gate contact is coupled to a gate connection portion 557 of the backside metallization structure. The second gate structure 570 has a second metal gate 574 coupled to second gate contact 575 (e.g., a via or other conductive structure, which in some aspects may be W formed in the MEOL), which is coupled to a second gate connection portion 577 of the frontside metallization structure. Accordingly, it will be appreciated that in the various aspects disclosed, the transistors (e.g., 501, 571) of apparatus 500 can be electrically connected on a first side (frontside) and/or second side (backside) for the gate, source, and drain. Further, it will be appreciated that although capable of being electrically connected on both sides, in some aspects, the gate, source, and/or drain may only be connected on one side. For example, both gate contact 555 and second gate contact 575 may be connected on the frontside and the drain and source may each only be connected on the backside.

FIG. 5D illustrates a partial cross-sectional view of the apparatus 500 of FIG. 5A in accordance with one or more aspects of the disclosure. Specifically, the cross-sectional view is illustrated along the CC′ line of FIG. 5A. The apparatus 500 includes a transistor 501 that has a source 520, where the source 520 includes the first source silicide layer 521 on the first side of the transistor 501 and a second source silicide layer 522 on a second side of the transistor 501. The first source silicide layer 521 is coupled to the first source contact 535 that is coupled to a first source via 534. The first source via 534 is coupled to a first source connection portion 544 (which in some aspects may be part of an interconnect in the frontside metallization structure, as discussed herein). The second source silicide layer 522 is coupled to the second source via 505. The second source via 505 is coupled to a second source connection portion 504 (which, as illustrated, may be part of an interconnect to second transistor 571 in the backside metallization structure). The frontside dielectric 562 is disposed on the frontside of transistor 501 and the backside dielectric 564 is disposed on an opposite side of the transistor 501, however, in some aspects, the frontside dielectric 562 and the backside dielectric 564 may form a generally homogeneous dielectric portion enclosing the transistor 501 and other transistors of the apparatus 500.

In some aspects, the drain 510 and the source 520 may be formed from one of Silicon or Carbon doped Silicon (SiC), e.g., for NFETs, or Silicon Germanium (SiGE), e.g., for PFETs. In some aspects, the second source connection portion 504, second drain connection portion 502, first drain connection portion 542, and first source connection portion 544 are formed from one or more of tungsten (W), cobalt (Co), copper (Cu), palladium (Pd), nickel (Ni), gold (Au), tantalum (Ta), tantalum nitride (TaN), titanium (Ti), titanium nitride (TiN), bismuth (Bi), antimony (Sb), molybdenum (Mo), and ruthenium (Ru) or any highly conductive material. In some aspects, the first drain via 532, second drain via 503, second source via 505, first source via 534, gate contact 555, and second gate contact 575 are formed of tungsten (W), cobalt (Co), ruthenium (Ru) or any highly conductive material.

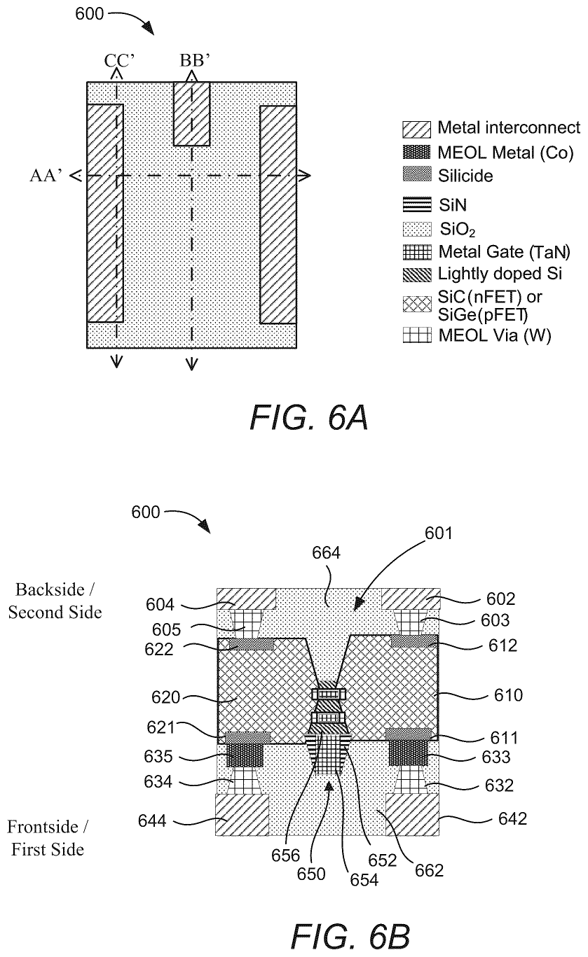

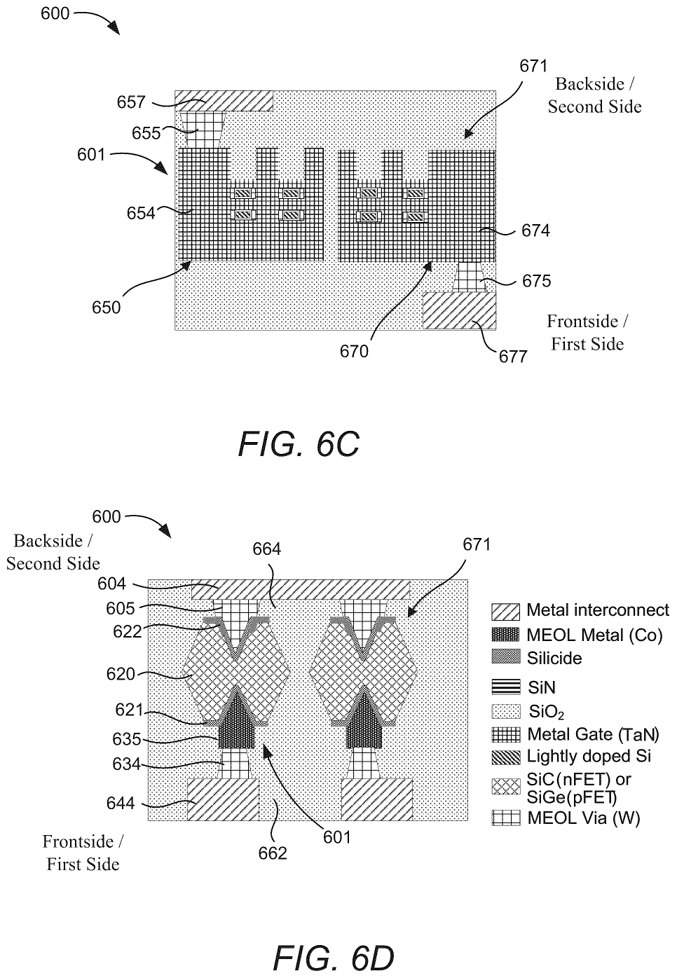

FIGS. 6A to 6D illustrate portions of an apparatus 600 including transistors with double-side contacts (contact structures)/dual-side contacts (contact structures) for the gate, source, and drain, which allows for electrical connection accessibility from both sides of the transistors and the silicon wafer. As noted above, aspects of the disclosure can improve the porosity (e.g., contact connection opportunities) and significantly decreases the area of standard cells including apparatus 600 according to various aspects of the disclosure.

FIG. 6A illustrates a top-down view of an apparatus 600 including a plurality of transistors in a cell configuration with various cut lines for cross-sectional views along cut lines AA′, BB′ and CC′, in subsequent FIGS. 6B, 6C and 6D.

FIG. 6B illustrates a cross-sectional portion of an apparatus 600 including GAA transistor 601 along line AA′, as illustrated in FIG. 6A. A gate structure 650 is disposed between a drain 610 and source 620. The gate structure 650 can include outer spacers 652, which in some aspects may be SiN or any suitable dielectric, metal gate 654, which in some aspects may be TaN or any suitable conductor, a gate oxide and inner gate spacers, as is known in the art. The metal gate 654 surrounds the plurality of channels 656, which in some aspects may be Si. The gate and channel structure of GAA transistors are well known, so a detailed description will not be provided herein. The drain 610 may include a first drain silicide layer 611 on the first side of the transistor 601 and a second drain silicide layer 612 on a second side of the transistor 601. The first drain silicide layer 611 is coupled to a first drain contact 633 (which in some aspects may be Co and may be formed in the MEOL) that is coupled to a first drain via 632 (which in some aspects may be W and may be formed in the MEOL). The first drain via 632 is coupled to a first drain connection portion 642 (which in some aspects may be part of a metal layer M0 metal interconnect in the frontside metallization structure, as discussed herein). The second drain silicide layer 612 is coupled to a second drain via 603. The second drain via 603 is coupled to a second drain connection portion 602 (which is part of a backside metallization structure, as discussed herein).

The source 620 may include a first source silicide layer 621 on a first side of the transistor 601 and a second source silicide layer 622 on a second side of the transistor 601. The first source silicide layer 621 is coupled to a first source contact 635 (which in some aspects may be Co and may be formed in the MEOL) that is coupled to a first source via 634 (which in some aspects may be W and may be formed in the MEOL). The first source via 634 is coupled to a first source connection portion 644 (which in some aspects may be part of a metal interconnect in a frontside metallization structure, as discussed herein). The second source silicide layer 622 is coupled to a second source via 605 (which in some aspects may be W and may be formed in the MEOL). The second source via 605 is coupled to a second drain connection portion 604 (which in some aspects may be part of a metal interconnect in a backside metallization structure, as discussed herein).

FIG. 6C illustrates a partial cross-sectional view of the apparatus 600 of FIG. 6A in accordance with one or more aspects of the disclosure. Specifically, the cross-sectional view is illustrated along the BB′ line of FIG. 6A. The apparatus 600 includes a transistor 601 that has a gate structure 650 as discussed above and a second transistor 671 with a second gate structure 670, which is similar to gate structure 650, so a detailed explanation will not be provided. Gate structure 650 has a gate via 655 coupled to a connection portion 657 of the backside metallization structure. Second gate structure 670 has a second gate via 675 coupled to a second gate connection portion 677 of the frontside metallization structure. Accordingly, it will be appreciated that transistors (e.g., 601, 671) of apparatus 600 can be electrically connected on both the first and second sides for the gate, source, and drain.

FIG. 6D illustrates a partial cross-sectional view of the apparatus 600 of FIG. 6A in accordance with one or more aspects of the disclosure. Specifically, the cross-sectional view is illustrated along the CC′ line of FIG. 6A. The apparatus 600 includes a transistor 601 that has a source 620, where the source 620 includes the first source silicide layer 621 on the first side of the transistor 601 and a second source silicide layer 622 on a second side of the transistor 601. The first source silicide layer 621 is coupled to the first source contact 635 that is coupled to a first source via 634. The first source via 634 is coupled to a first source connection portion 644 (which in some aspects may be part of an interconnect in the frontside metallization structure, as discussed herein). The second source silicide layer 622 is coupled to the second source via 605. The second source via 605 is coupled to a second drain connection portion 604 (which, as illustrated, may be part of an interconnect to second transistor 671 in the backside metallization structure). The frontside dielectric 662 is disposed on the frontside of transistor 601 and the backside dielectric 664 is disposed on an opposite side of the transistor 601, however, in some aspects, the frontside dielectric 662 and the backside dielectric 664 may form a generally homogeneous dielectric portion enclosing the transistor 601 and other transistors of the apparatus 600.

In some aspects, the drain 610 and the source 620 may be formed from one of Silicon or Carbon doped Silicon, e.g., for NFETs, or Silicon Germanium (SiGE), e.g., for PFETs. In some aspects, the second source connection portion 604, second drain connection portion 602, first drain connection portion 642, and first source connection portion 644 are formed from one or more of tungsten (W), cobalt (Co), copper (Cu), palladium (Pd), nickel (Ni), gold (Au), tantalum (Ta), tantalum nitride (TaN), titanium (Ti), titanium nitride (TiN), bismuth (Bi), antimony (Sb), molybdenum (Mo), and ruthenium (Ru) or any highly conductive material. In some aspects, the first drain via 632, second drain via 603, second source via 605 and first source via 634 are formed of tungsten (W) or any highly conductive material.

In view of the foregoing, it will be appreciated that one or more aspects can include an apparatus including a transistor (e.g., 501, 601) including a drain (e.g., 510, 610) including a first drain silicide layer (e.g., 511, 611) on a frontside surface of the drain (e.g., 510, 610) and a second drain silicide layer (e.g., 512, 612) on a backside surface of the drain (e.g., 510, 610). The first drain silicide layer (e.g., 511, 611) is coupled to a first drain contact structure (e.g., 532, 533 and 632, 633). The second drain silicide layer (e.g., 512, 612) is coupled to a second drain contact structure (e.g., 503, 603). The transistor (e.g., 501, 601) further includes a source (e.g., 520, 620) having a first source silicide layer (e.g., 521, 621) on a frontside surface of the source (e.g., 520, 620) and a second source silicide layer (e.g., 522, 622) on the backside surface of the source (e.g., 520, 620). The first source silicide layer (e.g., 521, 621) is coupled to a first source contact structure (e.g., 534, 535 and 634, 635). The second source silicide layer (e.g., 522, 622) is coupled to a second source contact structure (e.g., 505, 605). The transistor (e.g., 501, 601) includes a gate structure (e.g., 550, 650) disposed between the source (e.g., 520, 620) and the drain (e.g., 510, 610). The transistor (e.g., 501, 601) further includes a channel (e.g., 556, 656) at least partially enclosed by the gate structure (e.g., 550, 650) and disposed between the source (e.g., 520, 620) and the drain (e.g., 510, 610). The channel (e.g., 556, 656) is recessed from the backside surface of the source (e.g., 520, 620) and the backside surface of the drain (e.g., 510, 610).

In some aspects, the channel (e.g., 556, 656) is recessed in the range of 5 nanometers to 50 nanometers from the backside surface of the source (e.g., 520, 620) and the backside surface of the drain (e.g., 510, 610). In some aspects, the gate structure (e.g., 550, 650) includes a metal gate (e.g., 554, 654) coupled to a gate via (e.g., 555. 655) on the second side of the transistor (e.g., 501, 601). In some aspects, the first drain silicide layer (e.g., 511, 611), the second drain silicide layer (e.g., 512, 612), the first source silicide layer (e.g., 521, 621) and the second source silicide layer (e.g., 522, 622) have substantially a same thickness. In some aspects, a frontside metallization structure has a plurality of frontside metal layers, wherein the first drain via is coupled to a first drain connection portion (e.g., 542, 642) of the frontside metallization structure. The first source via (e.g., 534, 634) is coupled to a first source connection portion (e.g., 544, 644) of the frontside metallization structure. In some aspects, a backside metallization structure has a plurality of backside metal layers. The second drain via (e.g., 503, 603) is coupled to a second drain connection portion (e.g., 502, 602) of the backside metallization structure and the second source via (e.g., 505, 605) is coupled to a second source connection portion (e.g., 504, 604) of the backside metallization structure.

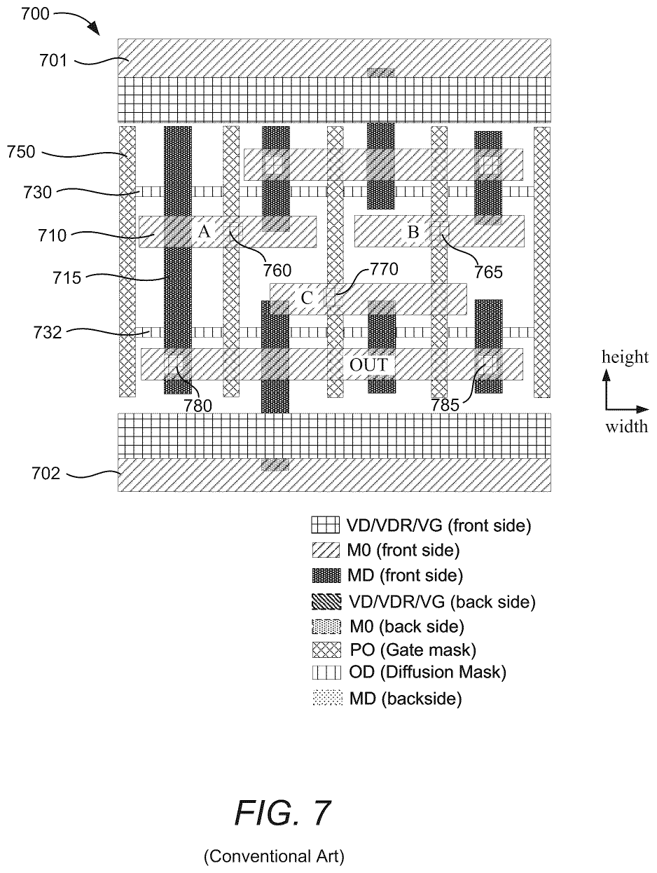

FIG. 7 illustrates a conventional layout of a standard cell 700. As discussed above, conventional standard cells only have frontside interconnections. Accordingly, all the input and output nodes (e.g., nodes A, B, C and OUT) will be coupled to associated frontside lines 710 (which in some aspects may be metal layer M0 in the frontside metallization structure), through frontside vias 760, 765, 770, 780 and 785, for nodes A, B, C and OUT, respectively. The standard cell 700 includes a plurality of gates 750 formed along the gate mask portions and diffusion regions 730 and 732 along the noted diffusion mask portions (e.g., p-diffusion or n-diffusion for forming PFET or NFET transistors, respectively). First local interconnect(s) 715 are used to provide interconnections in a path perpendicular to the frontside lines 710. Power is also provided from the frontside from VDD 701 and VSS 702 and may be metal layer M0 in the frontside metallization structure. Accordingly, with all the interconnections on the frontside, routing complexity is increased as is cell height and/or width. For example, including the five tracks frontside lines 710, VDD 701 and VSS 702, the cell height will have to accommodate at least 7 tracks. As used herein “tracks” refer to metal lines in the frontside metallization layer (e.g., M0) which can be used as interconnects for routing in the cell. It will be appreciated that a given track may have more than one interconnect. Additionally, the number of tracks generally defines a height of the standard cell. Accordingly, a standard cell with a greater number of tracks will have a greater height.

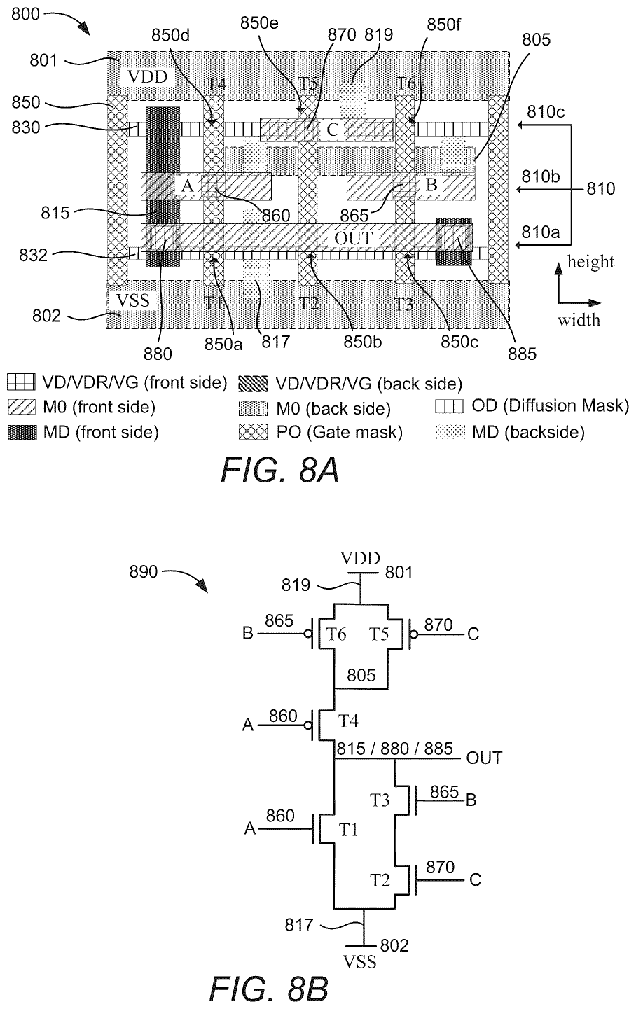

FIG. 8A illustrates a standard cell 800 in accordance with one or more aspects of the disclosure. The standard cell 800 is functionally equivalent to the conventional standard cell 700, but with a significantly reduced cell height. In contrast to the conventional standard cells which only have frontside interconnections, the standard cell 800 has both frontside and backside connections. In some aspects, the standard cell 800 is configured as an AND-OR-Inverter (AOI) device. The standard cell 800 can utilize the double-side (or dual side) contacts (or contact structures) of the various apparatuses (e.g., 100, 200, 300, 400, 500, 600, etc.), but should not be construed as being limited to these configurations. In some aspects of the disclosure, the input and output nodes (e.g., nodes A, B, C and OUT) can be coupled to either frontside lines 810a, 810b and 810c, one or more being part of the tracks 810 (which in some aspects may be metal layer M0 in the frontside metallization structure) or backside lines 801, 802, 805 (which in some aspects may be metal layer M0 in the backside metallization structure). It will be appreciated that “frontside line” and “backside line” refer to metal lines or traces in the metallization structure. Additionally, it will be appreciated that the a given “frontside line” and/or “backside line” can include multiple separate line portions, e.g., such as portions of frontside line 810b coupled to via 830 for input A and via 865 for input B. The vias coupling the nodes may be coupled to the frontside or the backside depending on the node connection. For example, OUT, A, B and C nodes use the frontside lines 810a, 810b and 810c, as illustrated. However, VDD and VSS use backside lines 801 and 802, respectively. Further, transistors T5 and T6 are coupled to each other by the backside line 805. Vias 860, 865, 870, 880 and 885 are used to couple nodes A, B, C and OUT to the associated frontside lines 810a-c. The standard cell 800 includes a plurality of transistors T1-T6, each comprising a gate structure (850a-850f) formed from a portion of one of the plurality of gates stacks 850 and one of the plurality of diffusion regions 830 or 832 (e.g., p-diffusion or n-diffusion for forming sources and drains for PFET or NFET transistors, respectively). A frontside local interconnect 815 is used to provide interconnections in a path perpendicular to the frontside lines 810a-c. Backside interconnects (e.g., backside interconnects 817 and 819) are used to provide interconnections in a path perpendicular to the backside lines 801, 802 and 805. Power is provided from the backside from backside line 801 (VDD) and backside line 802 (VSS). Backside lines 801, 802 and 805 may be on metal layer M0 in the backside metallization structure. For example, in the illustrated configuration, node C has an input connection from the frontside line 810a through via 870 to an associated gate structure 850e. However, the source and drain connections of transistors T5 and T6 are on the backside and are made through the backside interconnect 819 to the backside line 801 (VDD) and to each other the backside line 805.

Accordingly, with transistor gate, source and drain contacts/connections available on both the frontside and backside and interconnects on both the frontside and backside, routing complexity is reduced as is the cell height. For example, in the illustrated configuration, the cell height will only have to accommodate three tracks. In some aspects, with interconnects on both front/back sides, the standard cell height can be further reduced significantly by seventy percent or more. Transistors T1-T6 are labeled adjacent to their respective gates to avoid overcomplicating the figure. Additionally, these transistors and associated connections are detailed in relation to the associated schematic diagram of FIG. 8B.

FIG. 8B is a schematic 890 of the standard cell 800 of FIG. 8A, in accordance with one or more aspects of the disclosure. As noted above, the standard cell 800 is functionally equivalent to the conventional standard cell 700, so a schematic of standard cell 700 would also be similar. As noted above, the standard cell 800 can utilize the double-side contacts/interconnections and the input and output nodes (e.g., nodes A, B, C and OUT) can be coupled on either the frontside or the backside. To aid in relating the schematic 890 to standard cell 800, the inputs, outputs and other connections will be labeled in the schematic 890 along with transistors T1-T6. As illustrated, transistors T1 and T4 each have gates coupled to the input node A at via 860 on the frontside. Transistors T3 and T6 each have gates coupled to the input node B at via 865 on the frontside. Transistors T2 and T5 each have gates coupled to the input node C at via 870 on the frontside. The output node OUT (e.g., the frontside line 810a) is coupled to transistors T1 by via 880, T3 by via 885 and T4 by frontside local interconnect 815 and via 880. Transistors T5 and T6 are coupled to each other by the backside line 805 and are also coupled through backside interconnect 819 to backside line 801 (VDD). Transistors T1 and T2 are coupled through backside interconnect 817 to backside line 802 (VSS). As noted above, even with all the gate connections being on the frontside, the availability of the backside of the source and drain connections allows for the routing complexity and the cell height to be reduced. Accordingly, it will be appreciated that at least some of the various aspects disclosed include standard cells having transistors with contacts/contact structures/connections on the backside for at least one of the gate, source or drain. In some aspects, power is provided from backside lines (e.g., 801 (VDD) and 802 (VSS)).

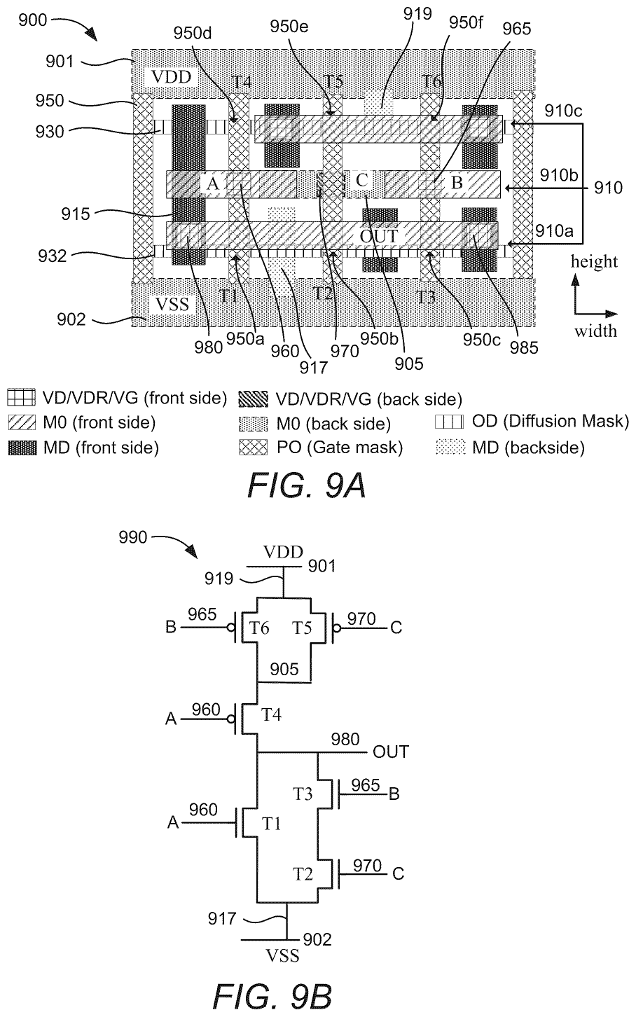

FIG. 9A illustrates a standard cell 900 in accordance with one or more aspects of the disclosure. The standard cell 900 is an AOI device and is functionally equivalent to the standard cells 700, but with a significantly reduced cell height. In contrast to the conventional standard cells which only have frontside connections, the standard cell 900 has both frontside and backside connections. The standard cell 900 can utilize the double-side contacts/interconnections of the various apparatuses and transistors (e.g., 100, 200, 300, 400, 500, 600, etc.) disclosed herein, but should not be construed as being limited to these configurations. Accordingly, the input and output nodes (e.g., nodes A, B, C and OUT) can be coupled to either frontside lines 910a, 910b and 910c, one or more being part of the tracks 910 (which in some aspects may be metal layer M0 in the frontside metallization structure) or backside lines 901, 902, 905 (which in some aspects may be metal layer BMO in the backside metallization structure). Likewise, the vias 960, 965, 970 and 980 coupling the nodes may be coupled to the frontside lines 910a-c or the backside lines 901, 902 and 905. For example, OUT, A and B nodes use the frontside lines 910a-c. However, VDD, VSS, and C nodes use backside lines 901, 902 and 905, respectively. Vias 960, 965 and 980 are used to couple nodes A, B and OUT, respectively, to the associated frontside lines 910a-c. In this example configuration, it will be appreciated that node C has an input from the backside line 905 through via 970. The standard cell 900 includes a plurality of gates stacks 950 (for forming gate structures 950a-950f) and diffusion regions 930 and 932 (e.g., p-diffusion or n-diffusion for forming PFET or NFET transistors, respectively). Frontside local interconnect(s) 915 are used to provide interconnections in a path perpendicular to the frontside lines 910a-c. Second local interconnect(s) 917 are used to provide interconnections in a path perpendicular to the backside lines 901, 902 and 905. Power is provided from the backside from backside lines 901 (VDD) and 902 (VSS) and may be on metal layer BMO in the backside metallization structure. In this illustrated configuration, also, the cell height will only have to accommodate three tracks.

FIG. 9B is a schematic 990 of the standard cell 900 of FIG. 9A, in accordance with one or more aspects of the disclosure. The standard cell 900 is functionally equivalent to the schematic 890 of standard cell 800, so the schematic 990 is similar, except for some of the noted frontside and backside nodes and connections. As noted above, the standard cell 900 can utilize the double-side contacts/connections, which allows transistor connections on the frontside, the backside or both. To aid in relating the schematic 990 to standard cell 900, the input and output nodes (e.g., nodes A, B, C and OUT) and other connections are labeled in the schematic 990 along with transistors T1-T6. As illustrated, transistors T1 and T4 each have gates coupled to the input node A at via 960 on the frontside. Transistors T3 and T6 each have gates coupled to the input node B at via 965 on the frontside. Transistors T2 and T5 each have gates coupled to the input node C at via 970 on the backside, which is also coupled to backside line 905, which serves as a signal line coupled to via 970 for input node C. The output node OUT (frontside line 910a) is coupled to transistors T1 by via 980, T3 by via 985, and T4 by frontside local interconnect 915 and via 980. Transistors T5 and T6 are also coupled through backside interconnect 919 to backside line 901 (VDD). Transistors T1 and T2 are coupled through backside interconnect 917 to backside line 902 (VSS). In contrast to the standard cell layout in FIG. 8A, input node C is coupled on the backside by via 970 to the input signal C from backside line 905. As discussed herein, the availability of frontside and backside connections for the gate, source and drain allows for the routing complexity and the cell height to be reduced. Accordingly, it will be appreciated that at least some of the various aspects disclosed include standard cells having transistors with contacts/connections on the backside for at least one of the gate, source or drain. In some aspects, power is provided from backside lines (e.g., 901 (VDD) and 902 (VSS)).

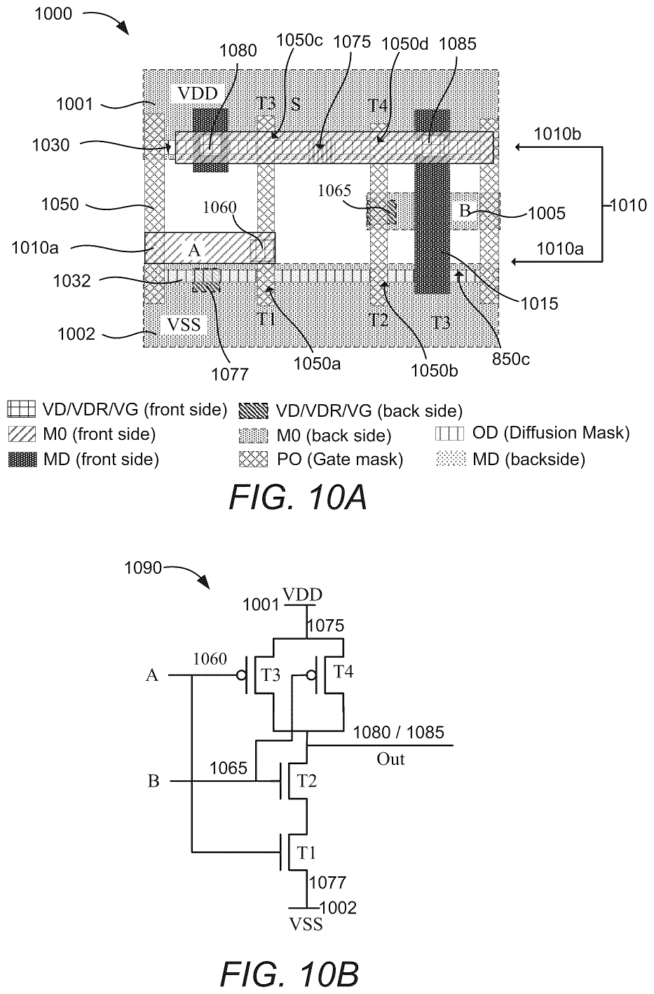

FIG. 10A illustrates a standard cell 1000 in accordance with one or more aspects of the disclosure. The standard cell 1000 is functionally equivalent to a NAND2 circuit and has a significantly reduced cell height in comparison to conventional standard cell configurations (e.g., 4 tracks vs. 2 tracks). In contrast to the conventional standard cells which only have frontside interconnections, the standard cell 1000 has both frontside and backside connections. The standard cell 1000 can utilize the double-side (i.e., frontside and backside) contacts/connections of the various apparatuses and transistors (e.g., 100, 200, 300, 400, 500, 600, etc.) disclosed herein but should not be construed as being limited to these configurations. Accordingly, the input and output nodes (e.g., nodes A, B, and OUT) can be coupled to either frontside lines 1010a and 1010b, or backside lines 1001, 1002, 1005 (which in some aspects may be metal layer BMO in the backside metallization structure). Tracks 1010 include one or more frontside lines 1010a-b (which in some aspects may be metal layer M0 in the frontside metallization structure). Likewise, the vias 1060, 1065 and 1080 coupling the nodes may be coupled to the frontside lines 1010a-b or the backside lines 1001, 1002 and 1005. For example, OUT and A nodes use the frontside lines 1010b and 1010a. However, VDD, VSS, and B nodes use backside lines 1001, 1002 and 1005. Vias 1060, and 1080 are used to couple nodes A and OUT to the associated frontside lines 1010a and 1010b, respectively. The standard cell 1000 includes a plurality of gate stacks 1050 (which can be used to form gate structures 1050a-1050d) and diffusion regions 1030 and 1032 (e.g., p-diffusion or n-diffusion for forming PFET or NFET transistors, respectively). Via 1065 couples input node B from backside line 1005 to associated gate structures (1050b and 1050d) of the plurality of gate stacks 1050. Frontside local interconnect(s) 1015 are used to provide interconnections in a path perpendicular to the frontside lines 1010a-b. Power is provided from the backside from backside lines 1001 (VDD) and 1002 (VSS). It will be appreciated that in some aspects, as illustrated, the backside lines 1002 (VSS) and/or 1002 (VSS) may extend over the diffusion regions 1030 (below frontside line 1010b) and 1032 to allow for direct connection to the transistors and other components. This can further reduce the standard cell height and reduce routing to/from the power lines. For example, via 1075 can directly couple backside line 1001 (VDD) to the source/drain of the PFET transistors associated with inputs A and B in the diffusion region 1030. Likewise, via 1077 can couple backside line 1002 (VSS) directly to the to the source/drain of an NFET transistor associated with input A in the diffusion region 1032. Additionally, due to the simplicity of the NAND2 configuration, the cell height will only have to accommodate 2 tracks 1010.

FIG. 10B is a schematic 1090 of the standard cell 1000 of FIG. 10A, in accordance with one or more aspects of the disclosure. The standard cell 1000 is functionally equivalent to a NAND gate device, which is represented by schematic 1090. As noted above, the standard cell 1000 can utilize the double-side contacts/interconnections and the input and output nodes (e.g., nodes A, B and OUT) which allows transistor contacts to be coupled on either the frontside or the backside. To aid in relating the schematic 1090 to standard cell 1000, the inputs, outputs and other connections are labeled in the schematic 1090 along with transistors T1-T6. As illustrated, transistors T1 and T3 each have gates coupled to the input node A at via 1060 on the frontside. Transistors T2 and T4 each have gates coupled to the input node B at via 1065 on the backside, which is also coupled to backside line 1005, which serves as an input signal line. The output node OUT (the frontside line 1010b) is coupled to transistors T3 by via 1080, T4 by via 1085, and T2, through frontside local interconnect 1015 to via 1085. Transistors T3 and T4 are coupled through via 1075 to backside line 1001 (VDD). Transistors T1 and T2 are coupled through via 1077 to backside line 1002 (VSS). As discussed herein, the availability of the frontside and backside connections for the gate, source and drain contacts allows for the routing complexity and the cell height to be reduced. Accordingly, it will be appreciated that at least some of the various aspects disclosed include standard cells having transistors with contacts/connections on the backside for at least one of the gate, source or drain. Further, in some aspects, power is provided from backside lines (e.g., 1001 (VDD) and 1002 (VSS)). In some aspects, backside line 1001, backside line 1002 or both may at least partially extend to or beyond the active regions to allow for direct coupling to the source or drain of at least one transistor on the backside. For example, as illustrated, the via 1077 is used to couple to 1002(VSS) and the via 1075 is used to couple to 1001(VDD) on the backside.

It will be appreciated, from the foregoing, that one or more aspects of the disclosure can include an apparatus including a semiconductor device having a standard cell. The apparatus (e.g., 1000, 900 800) includes a plurality of gate stacks (e.g., 850, 950, 1050) offset from each other in a first direction and disposed in a second direction opposite the first direction, a plurality of frontside lines (e.g., 810a-c, 910a-c, 1010a-b) disposed in the first direction, a plurality of backside lines (e.g., 1005, 1002, 1001, 905, 902, 901, 805, 802, 801) disposed in the first direction, and a plurality of frontside interconnects (e.g., 1015, 915, 815) adjacent the frontside lines (e.g., 1010a-b, 910a-c, 810a-c) and disposed in the first direction. The standard cell (e.g., 1000, 900 800) further includes a first transistor (e.g., 601, 501) having a first source (e.g., 620 520) and a first drain (e.g., 610, 510) each adjacent a first gate structure (e.g., 650, 550) of the plurality of gate stacks (e.g., 850, 950, 1050), wherein the first source (e.g., 620, 520) is coupled to a first backside line of the plurality of backside lines (e.g., 1005, 1002, 1001, 905, 902, 901, 805, 802, 801) and wherein the first drain (e.g., 610, 510) is coupled to a second backside line of the plurality of backside lines (e.g., 1005, 1002, 1001, 905, 902, 901, 805, 802, 801).

Additional aspects include the first transistor (e.g., 601, 501) further comprising a gate via (e.g., 555, 655) coupled to a metal gate (e.g., 654, 554) of the first gate structure (e.g., 650, 550) and coupled to one of the plurality of backside lines (e.g., 1005, 1002, 1001, 905, 902, 901, 805, 802, 801). For example, the via 970 couples the gate associated with node C to backside line 905, in FIG. 9A. Additionally, the standard cell can have transistors (e.g., 571 and 671) which have a gate via (e.g., 575, 675) coupled to a metal gate (e.g., 674, 554) of the gate structure (e.g., 670, 570) and coupled to one of the plurality of frontside lines (1010a-b, 910a-c, 810a-c).

In view of the disclosure herein, it will be appreciated that some further aspects can include an apparatus (e.g., 1000, 900 800) including a semiconductor device having a standard cell. The apparatus (e.g., 1000, 900 800) can include a plurality of frontside lines (e.g., 810a-c, 910a-c, 1010a-b); plurality of backside lines (e.g., 1005, 1002, 1001, 905, 902, 901, 805, 802, 801); a first diffusion region (e.g. N-type or P-type, 830, 832, 930, 932, 1030, 1032) extending in a first direction; a second diffusion region (e.g. N-type or P-type, 830, 832, 930, 932, 1030, 1032) extending in the first direction; a plurality of gate structures (e.g., 150, 550, 650, 850a-f, 950a-f, 1050a-d, etc.) offset from each other in the first direction and extending in a second direction perpendicular to the first direction; and a first transistor (e.g., 101, 501, 601, T1-T6, etc.) including: a first source (e.g., 120, 520, 620, etc.) and a first drain (e.g., 110, 510, 610, etc.) disposed in one of the first diffusion region (e.g. N-type or P-type, 830, 832, 930, 932, 1030, 1032) and the second diffusion region (e.g. N-type or P-type, 830, 832, 930, 932, 1030, 1032); a first gate structure (e.g., 150, 550, 650, 850a-f, 950a-f, 1050a-d, etc.), disposed in one of the plurality of gate structures (e.g., 150, 550, 650, 850a-f, 950a-f, 1050a-d, etc.) and disposed between the first source (e.g., 120, 520, 620, etc.) and the first drain (e.g., 110, 510, 610, etc.); and a first channel (e.g., 152, 556, 656, etc.), at least partially enclosed by the first gate structure (e.g., 150, 550, 650, 850a-f, 950a-f, 1050a-d, etc.), and disposed between the first source (e.g., 120, 520, 620, etc.) and the first drain (e.g., 110, 510, 610, etc.), wherein the first channel e.g., 152, 556, 656, etc.) is recessed from a backside surface of the first source (e.g., 120, 520, 620, etc.) and a backside surface of the first drain (e.g., 110, 510, 610, etc.), and wherein at least one of the first gate structure (e.g., 150, 550, 650, 850a-f, 950a-f, 1050a-d, etc.), the first source (e.g., 120, 520, 620, etc.), or the first drain (e.g., 110, 510, 610, etc.) is coupled to a first backside line of the plurality of backside lines (e.g., 1005, 1002, 1001, 905, 902, 901, 805, 802, 801).

Additional aspects include the apparatus (e.g., 1000, 900 800), further including one or more backside interconnects (e.g., 817, 819, 917, 919) disposed adjacent to the plurality of backside lines (e.g., 1005, 1002, 1001, 905, 902, 901, 805, 802, 801). Further aspects include the apparatus (e.g., 1000, 900 800), further including the first source (e.g., 120, 520, 620, etc.) and/or the first drain (e.g., 110, 510, 610, etc.) being coupled to the first backside line (e.g., 905, 902, 901, 805, 802, 801) through one of the one or more backside interconnects (e.g., 817, 819, 917, 919).

Additional aspects include the apparatus (e.g., 1000, 900 800), further including a frontside metallization structure (e.g., 360) having a plurality of frontside metallization layers (e.g., 360-0 to 360-n), wherein a first frontside metallization layer (e.g., 360-0) includes the plurality of frontside lines (e.g., 810a-c, 910a-c, 1010a-b), and a backside metallization (370) structure having a plurality of backside metallization layers (e.g., 370-0 to 370-m), wherein a first backside metallization layer includes the plurality of backside lines (e.g., 1005, 1002, 1001, 905, 902, 901, 805, 802, 801).

Additional aspects will be appreciated from the various aspects described herein and illustrated in the accompanying drawings. Further, as discussed above, the ability of the various aspects disclosed to have both frontside and backside connections for the gate, source and/or drain allows for the increased porosity and routing flexibility of standard cells in accordance with the various aspects disclosed.

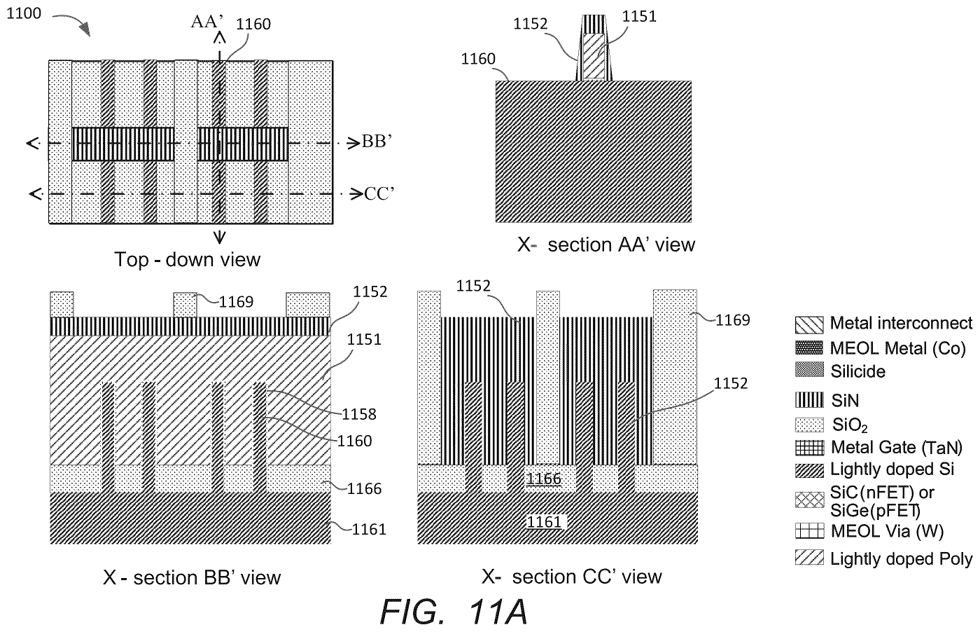

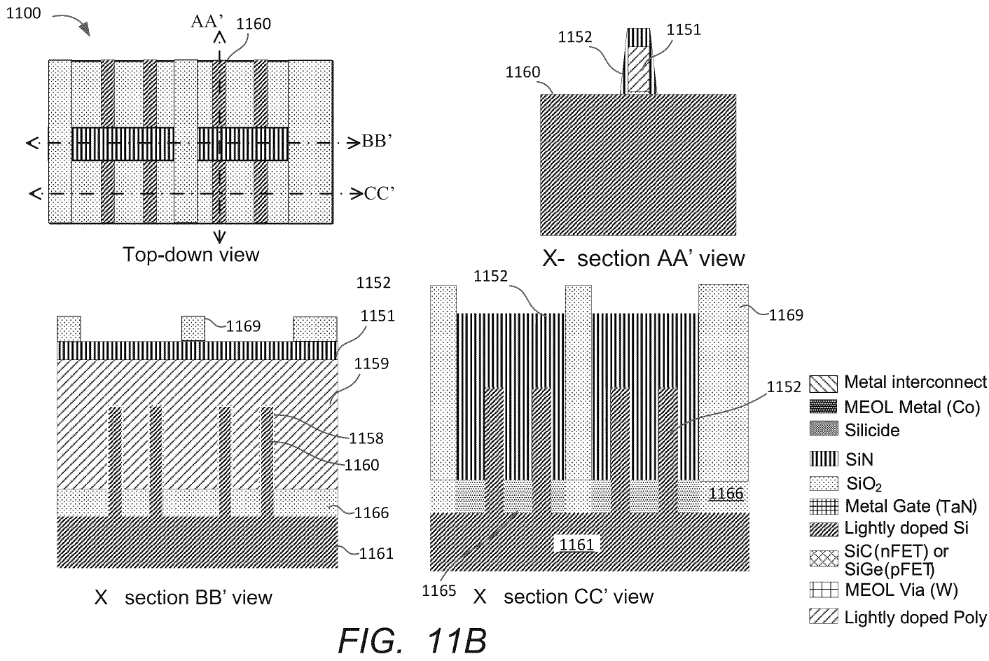

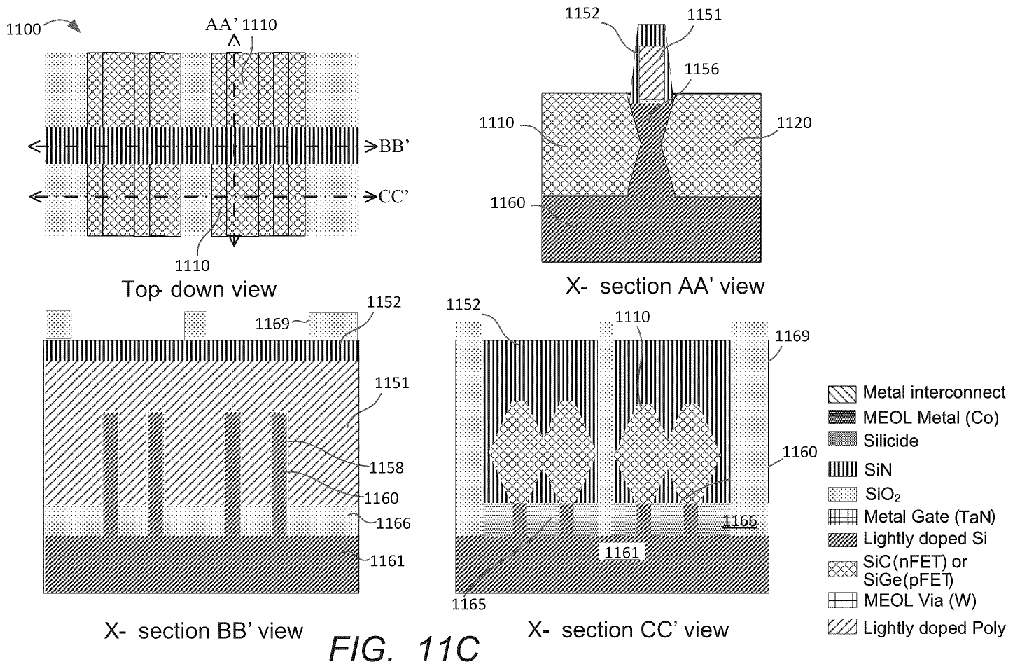

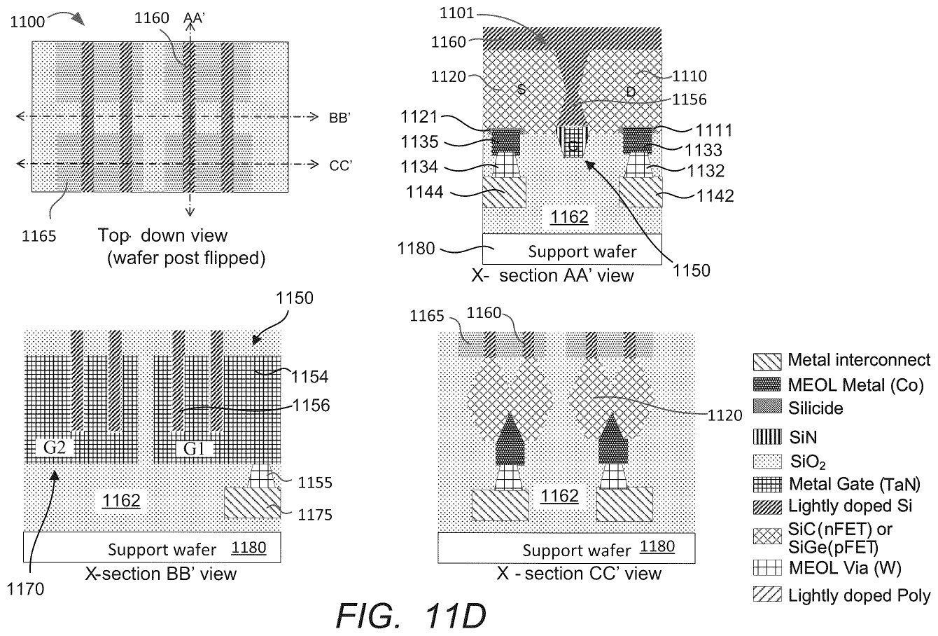

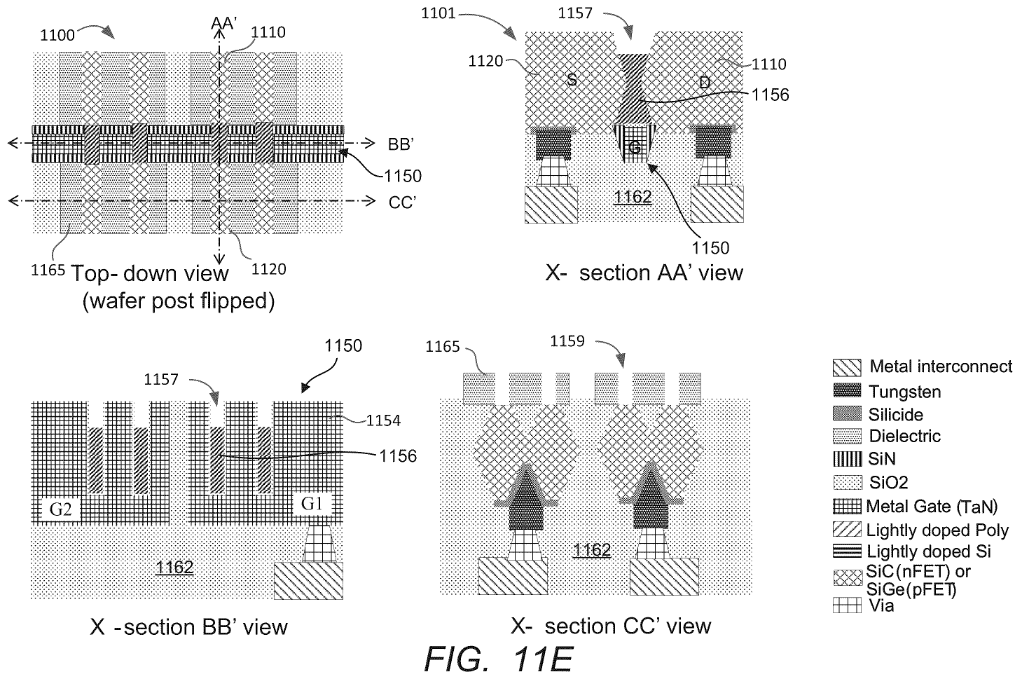

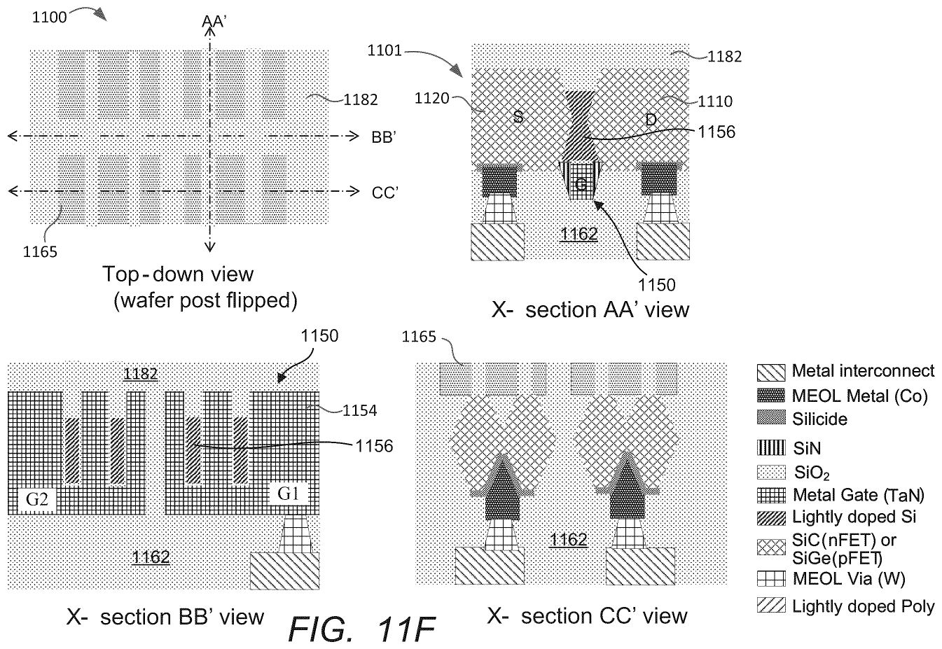

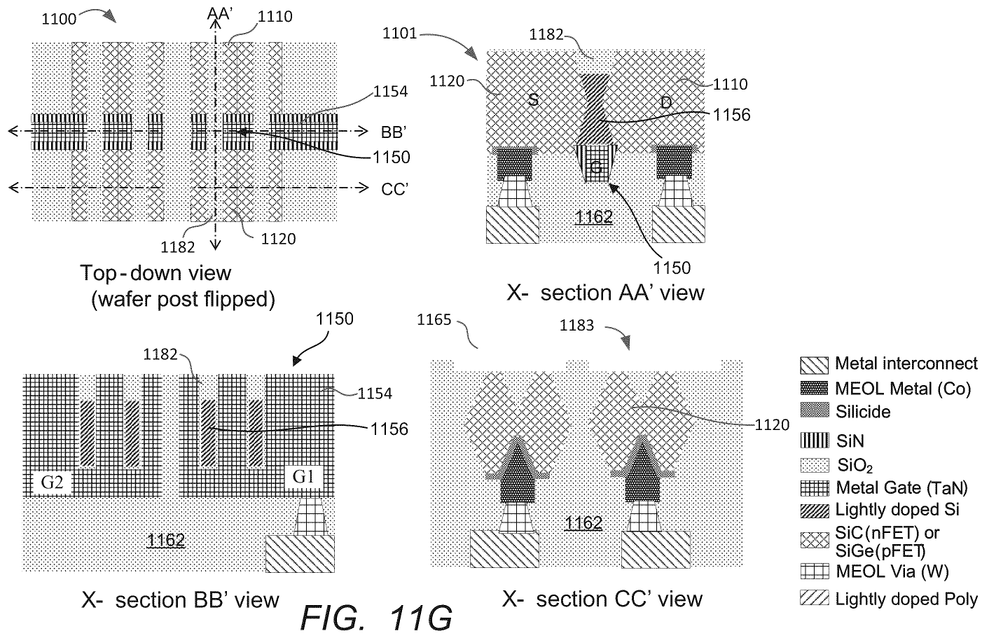

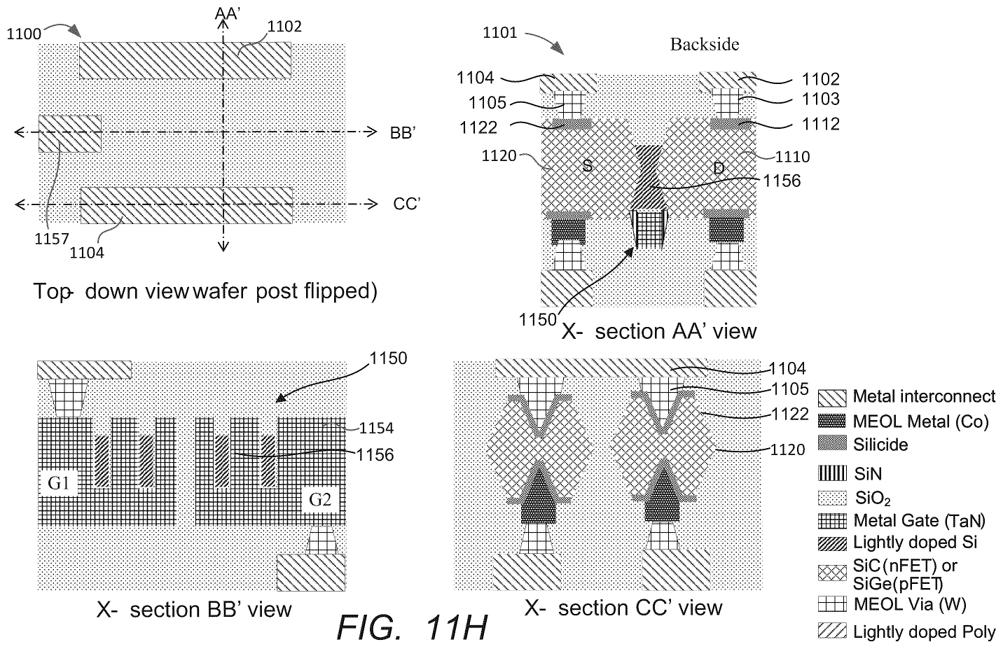

FIGS. 11A to 11H illustrate examples of methods of fabricating an integrated circuit/semiconductor structure in accordance with one or more aspects of the disclosure. In this instance, the stages may apply to the fabrication of an apparatus 1100 including at least one transistor similar to the foregoing apparatuses.

FIG. 11A illustrates a portion of a fabrication process for forming an apparatus 1100 (which in some aspects is similar to apparatus 500) in accordance with one or more aspects of the disclosure. In the illustration, a plan view and three cross-sectional views are provided. The cross-sectional views are along the AA′, BB′ and CC′ lines of the plan view, which is a top-down view. At this stage of the fabrication process, the fins 1160 and the dummy gate 1151 and gate spacer 1152 are formed, as illustrated in the cross-sectional view AA. The gate spacer 1152 in some aspects may be Silicon Nitride (SiN) The cross-sectional view BB′ is illustrated along the BB′ line and includes a plurality of fins 1160, which in some aspects are a lightly doped Si. The plurality of fins is surrounded by a gate oxide 1158, which in some aspects may be SiO₂, to isolate the fins 1160 from the dummy gate 1151. The dummy gate 1151 may be a lightly doped Polysilicon (Poly).

A buried oxide layer 1166, which in some aspects is SiO₂, is disposed on a substrate 1161 The substrate 1161 in some aspects is a lightly doped Si. Hard mask 1169 (which may also be SiO₂) provides isolation between groups of fins 1160 for the S/D epitaxial growth process. The cross-sectional view illustrated along the CC′ line (along the source/drain (S/D) region) includes similar elements viewed from the illustrated perspective, so repetition of the elements will not be repeated.

FIG. 11B illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view, which is a top-down view. At this stage of the fabrication process, the fins 1160, dummy gate 1151, gate spacer 1152 were previously formed, as illustrated in the cross-sectional view AA. The cross-sectional view BB,′ also remains unchanged with the previously described plurality of fins 1160, gate oxide 1158, dummy gate 1151, buried oxide layer 1166, substrate 1161 and hard mask 1169. At this stage, as can be seen in cross-sectional view CC,′ the process continues with opening a source/drain epitaxial (epi) window, etching buried oxide layer 1166 and depositing a second dielectric 1165, which is different from the buried oxide layer 1166 and some aspects may be SiN or Silicon oxynitride (SiON). The second dielectric 1165 is also visible in the plan view.

FIG. 11C illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view, which is a top-down view. At this stage of the fabrication process, the fins 1160, dummy gate 1151, gate spacer 1152 were previously formed, as illustrated in the cross-sectional view AA. The cross-sectional view BB′ continues unchanged with the previously described plurality of fins 1160, gate oxide 1158, dummy gate 1151, buried oxide layer 1166, substrate 1161 and hard mask 1169. At this stage, as can be seen in the plan view and cross-sectional views AA′ and CC′, the process continues performing an epi growth process on the exposed fins to form the sources and drains for the transistors of apparatus 1000. Each source 1120/drain 1110 (S/D) may be formed by epitaxial (epi) techniques that are commonly employed. Epitaxial growth includes the growth of a crystalline material (e.g., using SiC or SiGe) on the surface of the fins 1160. In some aspects, SiGe can be used for PFETs and SiC can be used for NFETs. Accordingly, a plurality of drains 1110 (drain epis) can each be grown epitaxially on one of the plurality of fins 1160. Likewise, sources 1120 (source epis) each be grown epitaxially on one of the plurality of fins. It will be appreciated For example, referring to cross-sectional view AA′ a drain 1110 and a source 1120 is illustrated with a channel 1156 being formed between the source 1120 and drain 1110. The source 1120 and drain 1110 are illustrated in the plan view and also illustrated in cross-sectional view CC′. It will be appreciated that reference to the source 1120, drain 1110, channel 1156, fins 1160, etc. also includes similar elements in the figures, which are not labeled to avoid redundancy and improve the clarity of the example figures. Accordingly, referring to process operations, features, etc. of the source 1120 would also apply to the other sources of apparatus 1100.

FIG. 11D illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view. The plan view is a top-down view post flip of the wafer, so the elements are inverted from the prior figures and the backside is facing up.

Prior to flipping, one or more of FEOL, frontside MEOL, and/or frontside BEOL processing is performed. For example, the gate polys are stripped and, in some aspects, a high dielectric constant (high-k or HK) metal gate structure 1150 is formed. The frontside contact structures are formed and use to couple the transistor 1101 to the frontside metallization structure formed in the BEOL (which is illustrated with one layer but may have more conductive layers) in a first dielectric 1162 adjacent the frontside of transistor 1101. After the frontside BEOL processing, in some aspects, a layer transfer technology process can be used to transfer the apparatus 1100 to the support wafer 1180.

Additionally, as illustrated, after the apparatus 1100 is flipped and attached to support wafer 1180, the substrate is removed. For example, an etch and/or CMP process can be performed to remove the substrate, which in some aspects stops at the second dielectric, which may be used as a shallow trench isolation structure.

At this stage of the fabrication process, the plurality of fins 1160 and the second dielectric 1165 are visible, from the backside, in the plan view. With the frontside processing completed, the cross-sectional view AA′ illustrates transistor 1101 which includes a gate structure 1150 is disposed between a drain 1110 and source 1120. A channel 1156 is disposed between the drain 1110 and the source 1120. The drain 1110 may include a first drain silicide layer 1111 on the frontside of the transistor 1101. The first drain silicide layer 1111 is coupled to a first drain contact 1133 (which in some aspects may be Co and may be formed in the MEOL) that is coupled to a first drain via 1132 (which in some aspects may be W and may be formed in the MEOL). The first drain silicide layer 1111, first drain via 1132 and first drain contact 1133 may generally be referred to as a first or frontside contact structure, as it will be appreciated that the electrical coupling on the frontside between the drain and the frontside metallization structure may include different configurations. The first drain via 1132 is coupled to a first drain connection portion 1142 (which is part of a frontside metallization structure, as discussed herein).

The source 1120 may include a first source silicide layer 1121 on the frontside of the transistor 1101. The first source silicide layer 1121 is coupled to a first source contact 1135 (which in some aspects may be Co and may be formed in the MEOL) that is coupled to a first source via 1134 (which in some aspects may be W and may be formed in the MEOL). The first source via 1134 is coupled to a first source connection portion 1144 (which is part of a frontside metallization structure, as discussed herein). The first source silicide layer 1121, first source contact 1135 and first source via 1134 may also generally be referred to as a frontside contact structure, as it will be appreciated that the electrical coupling on the frontside between the source and the frontside metallization structure may include different configurations.

As illustrated in cross-sectional view BB,′ the apparatus 1100 includes the transistor 1101 with the gate structure 1150 (G1), as discussed above, and a second transistor with a second gate structure 1170 (G2), which is similar to gate structure 1150, so a detailed explanation will not be provided. Gate structure 1150 has the metal gate 1154 coupled to a first gate contact 1155 (e.g., a MEOL via or other conductive structure, which in some aspects may be W). The gate contact 1155 is coupled to a gate connection portion 1175 of the frontside metallization structure. Cross-sectional view CC′ of the apparatus 1100 includes many common elements of the transistor 1101 discussed in reference to the foregoing cross-sections, so they will not be repeated for brevity.

FIG. 11E illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view. The plan view is a top-down view post flip of the wafer, so the elements are inverted, and the backside is facing up. Although the support wafer 1180 is removed in later processing stages (e.g., after FIG. 11H), the support wafer 1180 is no longer illustrated to reduce clutter in the drawings as its functionality is merely to provide support post flip during the backside processing. Further, all elements previously discussed are not relabeled. To aid in further discussion, the gate structure 1150, metal gate 1154, transistor 1101, the drain 1110, the source 1120, channel 1156, first dielectric 1162 and second dielectric 1165 are labeled in the various views.

At this stage of the process, the exposed Si elements (e.g., fins 1160/channel 1156) are etched down using a selective etch which is also self-aligned since only the Si portions will be removed. The selective etch does not etch the first dielectric 1162 (e.g., SiO₂), the second dielectric 1165 or metal gate 1154. Accordingly, after the selective etch process, a recess 1157 is formed between the source 1120 and drain 1110, where a portion of the channel 1156 used to be. For example, the channel height is less than the height of the source 1120 and drain 1110 as the channel height is reduced relative to the source 1120 and drain 1110, by the height of the channel recess 1157 in the channel area, which may be in a range of 5 nm to 50 nm. As illustrated, the channel 1156 is recessed from the backside surfaces of the source and drain, after the selective etch. Additionally, after the selective etch process, an S/D recess 1159 is also formed through the second dielectric.

FIG. 11F illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view. The plan view is a top-down view post flip of the wafer, so the elements are inverted, and the backside is facing up. To reduce clutter in the drawings all elements previously discussed are not relabeled. To aid in further discussion, the gate structure 1150, metal gate 1154, transistor 1101, the drain 1110, the source 1120, channel 1156, first dielectric 1162 and second dielectric 1165 are labeled in the various views.

At this stage of the process, a fill dielectric 1182 is deposited over the apparatus 1100 to fill the recesses formed in the prior stage. In some aspects, the fill dielectric 1182 comprises SiO₂. After the fill dielectric 1182 is deposited, a CMP process can be performed on the fill dielectric 1182 to planarize the surface and expose the second dielectric 1165. It will be appreciated that the second dielectric 1165 provides an integral mark for self-aligned processing over the S/D regions.

FIG. 11G illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view. The plan view is a top-down view post flip of the wafer, so the elements are inverted, and the backside is facing up. To reduce clutter in the drawings all elements previously discussed are not relabeled. To aid in further discussion, the gate structure 1150, metal gate 1154, transistor 1101, the drain 1110, the source 1120, channel 1156, and first dielectric 1162 are labeled in the various views.

At this stage of the process, the second dielectric 1165 over the S/D regions is removed and the fill dielectric 1182 is substantially removed (e.g., etching and/or CMP) from the apparatus 1100 to expose the metal gates (e.g., 1154), sources (e.g., 1120) and drains (e.g., 1110) in open windows between the dielectric covered portions, as can be seen from the plan view. It will be appreciated that residual portions of the fill dielectric 1182 cover the recessed channels 1156 (see, e.g., AA′ and BB′) provides the channels 1156 isolation from any potential shorting to the S/D contacts due to misalignment. Further, the recesses (e.g., recess 1183 in CC′) provide natural formed alignment marks, without the need for additional masks, for self-aligned processing over the S/D regions, e.g., for the formation of backside S/D contacts.

FIG. 11H illustrates a portion of a fabrication process for forming an apparatus 1100 in accordance with one or more aspects of the disclosure. In the illustration, a plan view and three cross-sectional views are provided. The cross-sectional views are along the AA′, BB′ and CC′ lines of the plan view. The plan view is a top-down view post flip of the wafer, so the elements are inverted, and the backside is facing up. To reduce clutter in the drawings all elements previously discussed are not relabeled. Further, it will be appreciated that the final structure of apparatus 1100 is similar to apparatus 500, discussed in detail above. To aid in further discussion, the gate structure 1150, metal gate 1154, transistor 1101, the drain 1110, the source 1120, and channel 1156 are labeled in the various views.

At this stage of the process, a BEOL process is performed on the backside to form gate, source, and drain backside contact structures and backside interconnections. For example, in some aspects, a second drain silicide layer 1112 is coupled to a second drain via 1103. The second drain via 1103 is coupled to a second drain connection portion 1102 (which is part of a first metal layer of a backside metallization structure, as discussed herein). The second drain silicide layer 1112 and second drain via 1103 may generally be referred to as a backside contact structure, as it will be appreciated that the electrical coupling on the backside between the drain and the backside metallization structure may include different configurations.

The second source silicide layer 1122 is coupled to a second source via 1105 (which in some aspects may be W and may be formed in the MEOL). The second source via 1105 is coupled to a second source connection portion 1104 (which is part of a backside metallization structure, as discussed herein). The second source silicide layer 1122 and second source via 1104 may also generally be referred to as a backside contact structure, as it will be appreciated that the electrical coupling on the backside between the source and the backside metallization structure may include different configurations.

It will be appreciated that the foregoing fabrication processes discussed in relation to FIGS. 11A-11H were provided merely as general illustrations of some of the aspects of the disclosure and are not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations. Additionally, it will be appreciated that various aspects disclosed for fabricating apparatuses including transistors with contacts on both the frontside and backside can be applied to different transistor configurations, such as FinFETs with more or less fins and Gate-All-Around (GAA) devices. Further, it will be appreciated that the apparatuses (e.g., 500, 600 and 1100) may comprise one or more standard cells such as discussed above in relation to standard cells 800, 900 and 1000 as the transistors of apparatuses (e.g., 500, 600 and 1100) have contact structures available on the frontside and backside to facilitate the frontside and backside connections that provide for the improved porosity and reduced number of tracks discussed above.

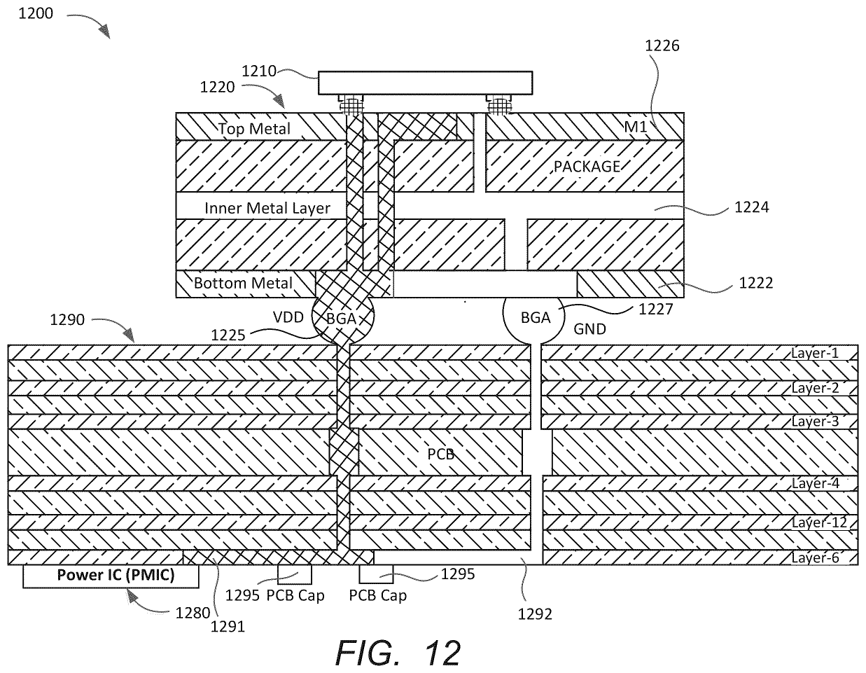

FIG. 12 illustrates components of an integrated device 1200 according to one or more aspects of the disclosure. Regardless of the various configurations of the apparatuses including transistors with double-side contacts/contact structures discussed above, it will be appreciated that any of these devices (e.g., 100, 200, 300, 400, 500, 600, 800, 900, 1000, 1100) can be configured as die 1210. It will be appreciated that various aspects are not limited to this configuration and more or less dies may be provided, with or without encapsulation. The package substrate 1220 may be configured to couple the die 1210 to a printed circuit board 1290 (PCB 1290). The PCB 1290 is also coupled to a power supply 1280 (e.g., a power management integrated circuit (PMIC), which allows the package substrate 1220 and the die 1210 to be electrically coupled to the PMIC 1280. Specifically, one or more power supply (VDD) lines 1291 and one or more ground (GND) lines 1292 may be coupled to the PMIC 1280 to distribute power to the PCB 1290, package substrate 1220 via VDD BGA pin 1225 and GND BGA pin 1227 and to the die 1210 coupled to the top metal layer/M1 layer 1226 of package substrate 1220. The package substrate 1220 has a bottom metal layer 1222 and may have one or more inner metal layers 1224, as is known in the art. It will be appreciated that the various aspects disclosed are not limited to any specific number of metal layers in the package substrate 1220. The VDD line 1291 and GND line 1292 each may be formed from traces, shapes, or patterns in one or more metal layers of the PCB 1290 (e.g., layers 1-6) coupled by one or more vias through insulating layers separating the metal layers 1-6 in the PCB 1290. The PCB 1290 may have one or more PCB capacitors (PCB cap) 1295 that can be used to condition the power supply signals, as is known to those skilled in the art. Additional connections and devices may be coupled to and/or pass through the PCB 1290 to the package substrate 1220 via one or more additional BGA pins (not illustrated) on the package substrate 1220. It will be appreciated that the illustrated configuration and descriptions are provided merely to aid in the explanation of the various aspects disclosed herein. For example, the PCB 1290 may have more or less metal and insulating layers, there may be multiple lines providing power to the various components, etc. Accordingly, the forgoing illustrative examples and associated figures should not be construed to limit the various aspects disclosed and claimed herein.

In order to fully illustrate aspects of the design of the present disclosure, methods of fabrication are discussed herein in relation to the various aspects disclosed. Other methods of fabrication are possible, and discussed fabrication methods are presented only to aid understanding of the concepts disclosed herein. It will be appreciated that any of the fabrication processes discussed were provided merely as general illustrations of some of the aspects of the disclosure and are not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

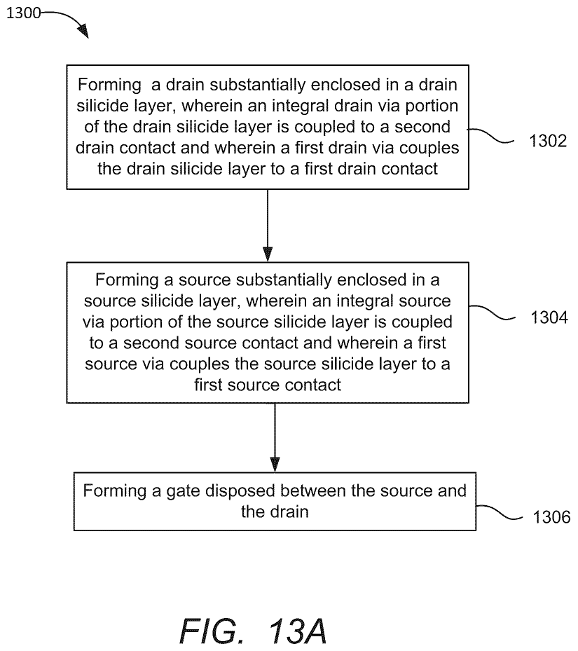

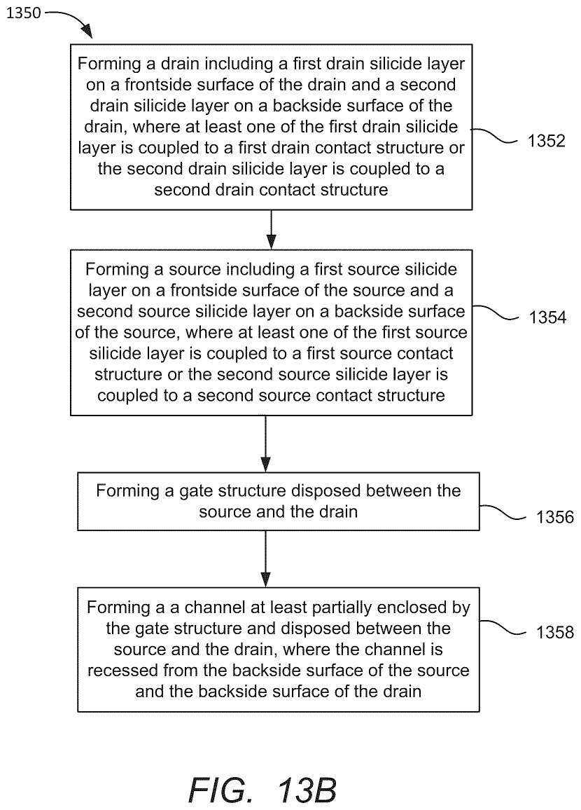

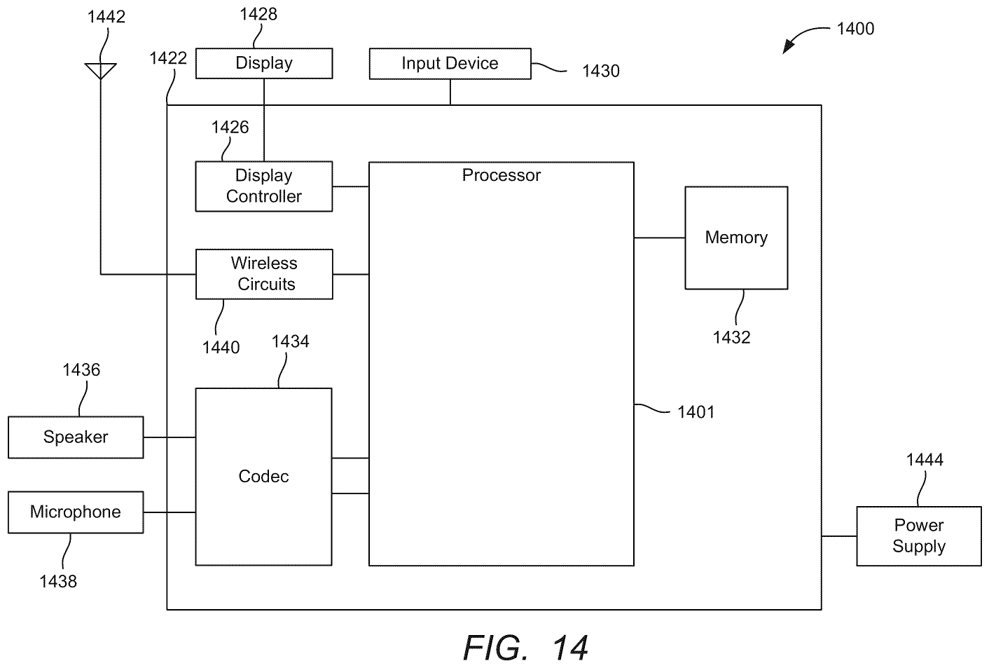

It will be appreciated from the foregoing that there are various methods for fabricating devices disclosed herein. FIG. 13A illustrates a flowchart of a method 1300 for fabricating an apparatus (e.g., 100, 200, 300, 400). The method can include forming a drain substantially enclosed in a drain silicide layer, wherein an integral drain via portion of the drain silicide layer is coupled to a second drain contact and wherein a first drain via couples the drain silicide layer to a first drain contact, at block 1302. The method further includes forming a source substantially enclosed in a source silicide layer, wherein an integral source via portion of the source silicide layer is coupled to a second source contact and wherein a first source via couples the source silicide layer to a first source contact, at block 1304. The method further includes forming a gate disposed between the source and the drain, at block 1306. It will be appreciated that the foregoing fabrication method is provided at a high level to highlight the fabrication of general novel aspects of the various aspects disclosed and is not intended to provide for detailed fabrication procedures, which can vary according to the various designs, as is known in the art.

Additionally, it will be appreciated from the foregoing that there are various methods for fabricating devices disclosed herein. FIG. 13B illustrates a flowchart of a method 1350 for fabricating an apparatus including a transistor (e.g., 500, 600, 800, 900, 1000, 1100). The method, in at least one aspect, at block 1352, includes forming a drain including a first drain silicide layer on a frontside surface of the drain and a second drain silicide layer on a backside surface of the drain, where at least one of the first drain silicide layer is coupled to a first drain contact structure or the second drain silicide layer is coupled to a second drain contact structure. The method, at block 1354, also includes forming a source including a first source silicide layer on a frontside surface of the source and a second source silicide layer on a backside surface of the source, where at least one of the first source silicide layer is coupled to a first source contact structure or the second source silicide layer is coupled to a second source contact structure. The method, at block 1356, also includes forming a gate structure disposed between the source and the drain. The method, at block 1358, also includes forming a channel at least partially enclosed by the gate structure and disposed between the source and the drain, where the channel is recessed from the backside surface of the source and the backside surface of the drain.

Accordingly, it will be appreciated from the foregoing disclosure that additional processes for fabricating the various aspects disclosed herein will be apparent to those skilled in the art and a literal rendition of the detailed processes related to the processes discussed above will not be provided or illustrated in the included drawings. It will be appreciated that the sequences of the fabrication processes are not necessarily in any order and later processes may be discussed earlier for convenience and to provide an example of the breadth of the various aspects disclosed.

The foregoing disclosed devices and functionalities may be designed and stored in computer files (e.g., register-transfer level (RTL), Geometric Data Stream (GDS) Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices, and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

FIG. 14 illustrates an exemplary mobile device in accordance with some examples of the disclosure. Referring now to FIG. 14, a block diagram of a mobile device that is configured according to exemplary aspects is depicted and generally designated mobile device 1400. In some aspects, mobile device 1400 may be configured as a wireless communication device. As shown, mobile device 1400 includes processor 1401. Processor 1401 may be communicatively coupled to memory 1432 over a link, which in some aspects may be a die-to-die or chip-to-chip link. Mobile device 1400 also includes display 1428 and display controller 1426, with display controller 1426 coupled to processor 1401 and to display 1428.

In some aspects, FIG. 14 may include coder/decoder (CODEC) 1434 (e.g., an audio and/or voice CODEC) coupled to processor 1401; speaker 1436 and microphone 1438 coupled to CODEC 1434; and wireless circuits 1440 coupled to wireless antenna 1442 and to processor 1401.

In one or more aspects, the processor 1401, memory 1432, wireless circuits 1440, and/or other components of mobile device 1400, may be implemented using one or more of the three-dimensional integrated circuit (3DIC) devices including transistor devices with double-side contacts and further including double-side contacts in FinFET and Gate-All-Around (GAA) devices, as disclosed herein).

In a particular aspect, where one or more of the above-mentioned blocks are present, processor 1401, display controller 1426, memory 1432, CODEC 1434, and wireless circuits 1440 can be included in a system-in-package or system-on-chip device 1422 which in some aspects may be implemented in whole or part using the various aspects disclosed herein. Input device 1430 (e.g., physical, or virtual keyboard), power supply 1444 (e.g., battery), display 1428, input device 1430, speaker 1436, microphone 1438, wireless antenna 1442, and power supply 1444 may be external to system-on-chip device 1422 and may be coupled to a component of system-on-chip device 1422, such as an interface or a controller.

It should be noted that although FIG. 14 depicts a mobile device 1400, processor 1401 and memory 1432 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

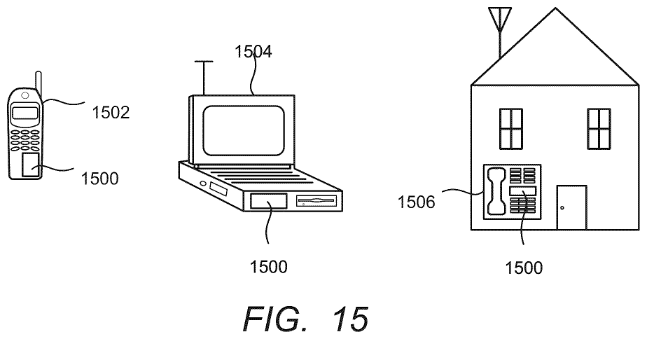

FIG. 15 illustrates various electronic devices that may be integrated with any of the aforementioned apparatuses/three-dimensional integrated circuit (3DIC) devices, in accordance with various examples of the disclosure. For example, a mobile phone device 1502, a laptop computer device 1504, and a fixed location terminal device 1506 may each be considered generally user equipment (UE) and may include a semiconductor device 1500 as described herein. The semiconductor device 1500 may be, for example, any of the integrated circuits, dies, integrated devices, integrated device packages, integrated circuit devices, device packages, integrated circuit (IC) packages, single die/multi-die/molded multi-chip devices, etc. described herein. The devices 1502, 1504, 1506 illustrated in FIG. 15 are merely exemplary. Other electronic devices may also feature the semiconductor device 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1A-15 may be rearranged and/or combined into a single component, process, feature, or function or incorporated in several components, processes, or functions. Additional elements, components, processes, and/or functions may also be added without departing from the disclosure. It should also be noted that FIGS. 1A-15 and corresponding description in the present disclosure are not limited to dies and/or ICs. In some implementations, FIGS. 1A-15 and the corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a system in package (SiP), a system on chip (SoC), a package on package (PoP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (WiFi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage, or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, however, these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer, or an electronic circuit. In some examples, some or a plurality of the most important method actions can be performed by such an apparatus.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses.

Clause 1. An apparatus comprising a transistor, the transistor comprising: a drain including a first drain silicide layer on a frontside surface of the drain and a second drain silicide layer on a backside surface of the drain, wherein at least one of the first drain silicide layer is coupled to a first drain contact structure or the second drain silicide layer is coupled to a second drain contact structure; a source including a first source silicide layer on a frontside surface of the source and a second source silicide layer on a backside surface of the source, wherein at least one of the first source silicide layer is coupled to a first source contact structure or the second source silicide layer is coupled to a second source contact structure; a gate structure disposed between the source and the drain; and a channel at least partially enclosed by the gate structure and disposed between the source and the drain, wherein the channel is recessed from the backside surface of the source and the backside surface of the drain.

Clause 2. The apparatus of clause 1, wherein the channel is recessed in a range of 5 nanometers to 50 nanometers from the backside surface of the source and the backside surface of the drain.

Clause 3. The apparatus of any of clauses 1 to 2, further comprising: a fill dielectric disposed between the source and the drain, wherein the fill dielectric extends from the channel to the backside surface of the source and the backside surface of the drain.

Clause 4. The apparatus of any of clauses 1 to 3, wherein a metal gate of the gate structure is coupled, by a gate frontside contact structure, to a first frontside metallization layer of a frontside metallization structure, or the metal gate is coupled, by a gate backside contact structure, to a first backside metallization layer of a backside metallization structure.

Clause 5. The apparatus of any of clauses 1 to 4, further comprising: a frontside metallization structure having one or more frontside metallization layers, wherein at least one of: the first drain contact structure is coupled to a first drain connection portion of the frontside metallization structure in a first frontside metallization layer, or the first source contact structure is coupled to a first source connection portion of the frontside metallization structure in the first frontside metallization layer.

Clause 6. The apparatus of any of clauses 1 to 5, further comprising: a backside metallization structure having one or more backside metallization layers, wherein at least one of: the second drain contact structure is coupled to a second drain connection portion of the backside metallization structure in a first backside metallization layer, or the second source contact structure is coupled to a second source connection portion of the backside metallization structure in the first backside metallization layer.

Clause 7. The apparatus of any of clauses 1 to 6, wherein the transistor is a fin field-effect transistor (FinFET) or a Gate-All-Around (GAA) transistor.

Clause 8. The apparatus of clause 7, wherein the FinFET comprises a plurality of fins.

Clause 9. The apparatus of clause 8, wherein the drain comprises a plurality of drains each grown epitaxially on one of the plurality of fins and wherein the second drain silicide layer is disposed between drains on adjacent fins of the plurality of fins, and wherein the source comprises a plurality of sources each grown epitaxially on one of the plurality of fins and wherein the second source silicide layer is disposed between sources on adjacent fins of the plurality of fins.

Clause 10. The apparatus of any of clauses 1 to 9, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

Clause 11. An apparatus, comprising: a plurality of frontside lines; a plurality of backside lines; a first diffusion region extending in a first direction; a second diffusion region extending in the first direction; a plurality of gate structures offset from each other in the first direction and extending in a second direction perpendicular to the first direction; and a first transistor comprising: a first source and a first drain disposed in one of the first diffusion region and the second diffusion region; a first gate structure, disposed in one of the plurality of gate structures and disposed between the first source and the first drain; and a first channel, at least partially enclosed by the first gate structure, and disposed between the first source and the first drain, wherein the first channel is recessed from a backside surface of the first source and a backside surface of the first drain, and wherein at least one of the first gate structure, the first source, or the first drain is coupled to a first backside line of the plurality of backside lines.

Clause 12. The apparatus of clause 11, wherein the first gate structure further comprises a metal gate coupled to a first gate via coupled to one of the plurality of backside lines.

Clause 13. The apparatus of clause 11, wherein the first gate structure further comprises a metal gate coupled to a first gate via coupled to one of the plurality of frontside lines.

Clause 14. The apparatus of any of clauses 11 to 13, further comprising: one or more backside interconnects disposed adjacent to the plurality of backside lines.

Clause 15. The apparatus of clause 14, wherein the first source is coupled to the first backside line through one of the one or more backside interconnects.

Clause 16. The apparatus of clause 14, wherein the first drain is coupled to the first backside line through one of the one or more backside interconnects.

Clause 17. The apparatus of any of clauses 11 to 16, wherein the first backside line is coupled to a first power source at a positive potential and a second backside line of the plurality of backside lines is coupled to a second power source at a ground or negative potential.

Clause 18. The apparatus of any of clauses 11 to 17, further comprising: a frontside metallization structure having a plurality of frontside metallization layers, wherein a first frontside metallization layer comprises the plurality of frontside lines; and a backside metallization structure having a plurality of backside metallization layers, wherein a first backside metallization layer comprises the plurality of backside lines.

Clause 19. The apparatus of any of clauses 11 to 18, wherein at least one of: the first drain includes a first drain silicide layer on a frontside surface of the first drain and a second drain silicide layer on a backside surface of the first drain, wherein the second drain silicide layer is coupled to a second drain contact structure coupled to one of the plurality of backside lines; or the first source includes a first source silicide layer on a frontside surface of the first source and a second source silicide layer on the backside surface of the first source, wherein the second source silicide layer is coupled to a second source contact structure coupled to one of the plurality of backside lines.

Clause 20. The apparatus of any of clauses 11 to 19, further comprising: a plurality of tracks each of which comprise one or more of the plurality of frontside lines, wherein the plurality of tracks is two or three tracks.

Clause 21. A method for fabricating an apparatus including a transistor, the method comprising: forming a drain including a first drain silicide layer on a frontside surface of the drain and a second drain silicide layer on a backside surface of the drain, wherein at least one of the first drain silicide layer is coupled to a first drain contact structure or the second drain silicide layer is coupled to a second drain contact structure; forming a source including a first source silicide layer on a frontside surface of the source and a second source silicide layer on a backside surface of the source, wherein at least one of the first source silicide layer is coupled to a first source contact structure or the second source silicide layer is coupled to a second source contact structure; forming a gate structure disposed between the source and the drain; and forming a channel at least partially enclosed by the gate structure and disposed between the source and the drain, wherein the channel is recessed from the backside surface of the source and the backside surface of the drain.

Clause 22. The method of clause 21, wherein the channel is recessed in a range of 5 nanometers to 50 nanometers from the backside surface of the source and the backside surface of the drain.

Clause 23. The method of any of clauses 21 to 22, further comprising: depositing a fill dielectric between the source and the drain, wherein the fill dielectric extends from the channel to the backside surface of the source and the backside surface of the drain.

Clause 24. The method of any of clauses 21 to 23, further comprising: coupling, by a gate frontside contact structure, a metal gate of the gate structure to a first frontside metallization layer of a frontside metallization structure, or the metal gate to a gate backside contact structure, to a first backside metallization layer of a backside metallization structure.

Clause 25. The method of any of clauses 21 to 24, further comprising: forming a frontside metallization structure having one or more frontside metallization layers, wherein at least one of: the first drain contact structure is coupled to a first drain connection portion of the frontside metallization structure in a first frontside metallization layer, or the first source contact structure is coupled to a first source connection portion of the frontside metallization structure in the first frontside metallization layer.

Clause 26. The method of any of clauses 21 to 25, further comprising: forming a backside metallization structure having one or more backside metallization layers, wherein at least one of: the second drain contact structure is coupled to a second drain connection portion of the backside metallization structure in a first backside metallization layer, or the second source contact structure is coupled to a second source connection portion of the backside metallization structure in the first backside metallization layer.

Clause 27. The method of any of clauses 21 to 26, wherein the transistor is a fin field-effect transistor (FinFET) or a Gate-All-Around (GAA) transistor.

Clause 28. The method of clause 27, wherein the FinFET comprises a plurality of fins.

Clause 29. The method of clause 28, wherein the drain comprises a plurality of drains each grown epitaxially on one of the plurality of fins and wherein the second drain silicide layer is disposed between drains on adjacent fins of the plurality of fins, and wherein the source comprises a plurality of sources each grown epitaxially on one of the plurality of fins and wherein the second source silicide layer is disposed between sources on adjacent fins of the plurality of fins.

Clause 30. The method of any of clauses 21 to 29, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus comprising a transistor, the transistor comprising:
a drain including a first drain silicide layer on a frontside surface of the drain and a second drain silicide layer on a backside surface of the drain, wherein at least one of the first drain silicide layer is coupled to a first drain contact structure or the second drain silicide layer is coupled to a second drain contact structure;
a source including a first source silicide layer on a frontside surface of the source and a second source silicide layer on a backside surface of the source, wherein at least one of the first source silicide layer is coupled to a first source contact structure or the second source silicide layer is coupled to a second source contact structure;
a gate structure disposed between the source and the drain; and
a channel at least partially enclosed by the gate structure and disposed between the source and the drain, wherein the channel is recessed from the backside surface of the source and the backside surface of the drain.

2. The apparatus of claim 1, wherein the channel is recessed in a range of 5 nanometers to 50 nanometers from the backside surface of the source and the backside surface of the drain.

3. The apparatus of claim 1, further comprising:
a fill dielectric disposed between the source and the drain, wherein the fill dielectric extends from the channel to the backside surface of the source and the backside surface of the drain.

4. The apparatus of claim 1, wherein a metal gate of the gate structure is coupled, by a gate frontside contact structure, to a first frontside metallization layer of a frontside metallization structure, or the metal gate is coupled, by a gate backside contact structure, to a first backside metallization layer of a backside metallization structure.

5. The apparatus of claim 1, further comprising:
a frontside metallization structure having one or more frontside metallization layers, wherein at least one of:
the first drain contact structure is coupled to a first drain connection portion of the frontside metallization structure in a first frontside metallization layer, or
the first source contact structure is coupled to a first source connection portion of the frontside metallization structure in the first frontside metallization layer.

6. The apparatus of claim 1, further comprising:
a backside metallization structure having one or more backside metallization layers, wherein at least one of:
the second drain contact structure is coupled to a second drain connection portion of the backside metallization structure in a first backside metallization layer, or
the second source contact structure is coupled to a second source connection portion of the backside metallization structure in the first backside metallization layer.

7. The apparatus of claim 1, wherein the transistor is a fin field-effect transistor (FinFET) or a Gate-All-Around (GAA) transistor.

8. The apparatus of claim 7, wherein the FinFET comprises a plurality of fins.

9. The apparatus of claim 8, wherein the drain comprises a plurality of drains each grown epitaxially on one of the plurality of fins and wherein the second drain silicide layer is disposed between drains on adjacent fins of the plurality of fins, and
wherein the source comprises a plurality of sources each grown epitaxially on one of the plurality of fins and wherein the second source silicide layer is disposed between sources on adjacent fins of the plurality of fins.

10. The apparatus of claim 1, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

11. An apparatus, comprising:
a plurality of frontside lines;
a plurality of backside lines;
a first diffusion region extending in a first direction;
a second diffusion region extending in the first direction;
a plurality of gate structures offset from each other in the first direction and extending in a second direction perpendicular to the first direction;
and
a first transistor comprising:
a first source and a first drain disposed in one of the first diffusion region and the second diffusion region;
a first gate structure, disposed in one of the plurality of gate structures and disposed between the first source and the first drain; and
a first channel, at least partially enclosed by the first gate structure, and disposed between the first source and the first drain, wherein the first channel is recessed from a backside surface of the first source and a backside surface of the first drain, and
wherein at least one of the first gate structure, the first source, or the first drain is coupled to a first backside line of the plurality of backside lines.

12. The apparatus of claim 11, wherein the first gate structure further comprises a metal gate coupled to a first gate via coupled to one of the plurality of backside lines.

13. The apparatus of claim 11, wherein the first gate structure further comprises a metal gate coupled to a first gate via coupled to one of the plurality of frontside lines.

14. The apparatus of claim 11, further comprising:
one or more backside interconnects disposed adjacent to the plurality of backside lines.

15. The apparatus of claim 14, wherein the first source is coupled to the first backside line through one of the one or more backside interconnects.

16. The apparatus of claim 14, wherein the first drain is coupled to the first backside line through one of the one or more backside interconnects.

17. The apparatus of claim 11, wherein the first backside line is coupled to a first power source at a positive potential and a second backside line of the plurality of backside lines is coupled to a second power source at a ground or negative potential.

18. The apparatus of claim 11, further comprising:
a frontside metallization structure having a plurality of frontside metallization layers, wherein a first frontside metallization layer comprises the plurality of frontside lines; and
a backside metallization structure having a plurality of backside metallization layers, wherein a first backside metallization layer comprises the plurality of backside lines.

19. The apparatus of claim 11, wherein at least one of:
the first drain includes a first drain silicide layer on a frontside surface of the first drain and a second drain silicide layer on a backside surface of the first drain, wherein the second drain silicide layer is coupled to a second drain contact structure coupled to one of the plurality of backside lines; or
the first source includes a first source silicide layer on a frontside surface of the first source and a second source silicide layer on the backside surface of the first source, wherein the second source silicide layer is coupled to a second source contact structure coupled to one of the plurality of backside lines.

20. The apparatus of claim 11, further comprising:
a plurality of tracks each of which comprise one or more of the plurality of frontside lines, wherein the plurality of tracks is two or three tracks.

21. A method for fabricating an apparatus including a transistor, the method comprising:
forming a drain including a first drain silicide layer on a frontside surface of the drain and a second drain silicide layer on a backside surface of the drain, wherein at least one of the first drain silicide layer is coupled to a first drain contact structure or the second drain silicide layer is coupled to a second drain contact structure;
forming a source including a first source silicide layer on a frontside surface of the source and a second source silicide layer on a backside surface of the source, wherein at least one of the first source silicide layer is coupled to a first source contact structure or the second source silicide layer is coupled to a second source contact structure;
forming a gate structure disposed between the source and the drain; and
forming a channel at least partially enclosed by the gate structure and disposed between the source and the drain, wherein the channel is recessed from the backside surface of the source and the backside surface of the drain.

22. The method of claim 21, wherein the channel is recessed in a range of 5 nanometers to 50 nanometers from the backside surface of the source and the backside surface of the drain.

23. The method of claim 21, further comprising:
depositing a fill dielectric between the source and the drain, wherein the fill dielectric extends from the channel to the backside surface of the source and the backside surface of the drain.

24. The method of claim 21, further comprising:
coupling, by a gate frontside contact structure, a metal gate of the gate structure to a first frontside metallization layer of a frontside metallization structure, or the metal gate to a gate backside contact structure, to a first backside metallization layer of a backside metallization structure.

25. The method of claim 21, further comprising:
forming a frontside metallization structure having one or more frontside metallization layers, wherein at least one of:
the first drain contact structure is coupled to a first drain connection portion of the frontside metallization structure in a first frontside metallization layer, or
the first source contact structure is coupled to a first source connection portion of the frontside metallization structure in the first frontside metallization layer.

26. The method of claim 21, further comprising:
forming a backside metallization structure having one or more backside metallization layers, wherein at least one of:
the second drain contact structure is coupled to a second drain connection portion of the backside metallization structure in a first backside metallization layer, or
the second source contact structure is coupled to a second source connection portion of the backside metallization structure in the first backside metallization layer.

27. The method of claim 21, wherein the transistor is a fin field-effect transistor (FinFET) or a Gate-All-Around (GAA) transistor.

28. The method of claim 27, wherein the FinFET comprises a plurality of fins.

29. The method of claim 28, wherein the drain comprises a plurality of drains each grown epitaxially on one of the plurality of fins and wherein the second drain silicide layer is disposed between drains on adjacent fins of the plurality of fins, and
wherein the source comprises a plurality of sources each grown epitaxially on one of the plurality of fins and wherein the second source silicide layer is disposed between sources on adjacent fins of the plurality of fins.

30. The method of claim 21, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.
